(19) United States
(12) Patent Application Publication
(10) Pub. No.: US 2026/0203473 A1
(43) Pub. Date: Jul. 16, 2026

(54) APPARATUS AND METHODS USING SEPARABLE NEURAL NETWORKS FOR CHARACTERIZATION OF ELECTRIC MOTORS

(71) Applicant: Monumo Limited, Cambridge (GB)

(72) Inventors: Daniel Bates, Cambridge (GB); Nicolas Durrande, Cambridge (GB); Mi Tang, Nottingham (GB); Rupert Tombs, Saffron Walden (GB)

(21) Appl. No.: 19/019,179

(22) Filed: Jan. 13, 2025

(51) Int. Cl. G06F 30/27; G06F 30/17

(52) U.S. Cl. CPC G06F 30/27; G06F 30/17

(57) ABSTRACT

The techniques described herein relate to systems and methods for using separable neural networks for characterization of electric motors. An example method for processing multiple electric motor designs into outputs of respective performance evaluations across different operating conditions using machine learning includes mapping input geometric parameters to at least one of a plurality of electric motor designs, and inputting the plurality of electric motor designs to at least one machine learning model and outputting, from the at least one machine learning model, performance evaluations for the plurality of electric motor designs under a variety of operating conditions, the at least one machine learning model trained to generate the performance evaluations in accordance with control waveforms for the plurality of electric motor designs.

### FIELD

The techniques described herein relate to systems, apparatus, articles of manufacture, and methods for using separable neural networks for characterization of electric motors.

### BACKGROUND

Electric motors are devices that convert electrical energy to mechanical energy, which typically takes the form of rotational motion. Electric motors convert electrical energy to mechanical energy through electromagnetics such as through the interaction of the electric motor's magnetic field and electric current in a wound wire to generate force that generates torque applied on the electric motor's shaft, which transfers energy as the shaft rotates. Common applications for electric motors include electric vehicles, industrial machinery, household appliances, and machine tools.

### SUMMARY

In accordance with the disclosed subject matter, systems, apparatus, articles of manufacture, and methods are provided for electric motor design and/or using separable neural networks for characterization of electric motors.

Some embodiments relate to a method for processing multiple electric motor designs into outputs of respective performance evaluations across different operating conditions using machine learning. The method comprises mapping input geometric parameters to at least one of a plurality of electric motor designs, and inputting the plurality of electric motor designs to at least one machine learning model and outputting, from the at least one machine learning model, performance evaluations for the plurality of electric motor designs under a variety of operating conditions, the at least one machine learning model trained to generate the performance evaluations in accordance with control waveforms for the plurality of electric motor designs.

Some embodiments relate to at least one computer readable storage medium comprising processor executable instructions that, when executed, cause at least one hardware processor to at least map input geometric parameters to at least one of a plurality of electric motor designs, and input the plurality of electric motor designs to at least one machine learning model and output, from the at least one machine learning model, performance evaluations for the plurality of electric motor designs under a variety of operating conditions, the at least one machine learning model trained to generate the performance evaluations in accordance with control waveforms for the plurality of electric motor designs.

Some embodiments relate to a system for processing multiple electric motor designs into outputs of respective performance evaluations across different operating conditions using machine learning comprising at least one hardware processor, and at least one computer readable storage medium storing processor executable instructions that, when executed by the at least one hardware processor, cause the at least one hardware processor to map input geometric parameters to at least one of a plurality of electric motor designs, and input the plurality of electric motor designs to at least one machine learning model and output, from the at least one machine learning model, performance evaluations for the plurality of electric motor designs under a variety of operating conditions, the at least one machine learning model trained to generate the performance evaluations in accordance with control waveforms for the plurality of electric motor designs.

Some embodiments relate to a method for characterizing an electric motor design using machine learning. The method comprises inputting a set of geometric parameters for an electric motor design to a first machine learning model and outputting, from the first machine learning model, an encoding of the set of geometric parameters, and inputting a control waveform and the encoding of the set of geometric parameters to a second machine learning model and outputting, from the second machine learning model, a performance of the electric motor design under a variety of operating conditions and using the control waveform.

Some embodiments relate to at least one computer readable storage medium comprising processor executable instructions that, when executed, cause at least one hardware processor to at least input a set of geometric parameters for an electric motor design to a first machine learning model and output, from the first machine learning model, an encoding of the set of geometric parameters, and input a control waveform and the encoding of the set of geometric parameters to a second machine learning model and output, from the second machine learning model, a performance of the electric motor design under a variety of operating conditions and using the control waveform.

Some embodiments relate to a system for characterizing an electric motor design using machine learning, comprising: at least one hardware processor, and at least one computer readable storage medium storing processor executable instructions that, when executed by the at least one hardware processor, cause the at least one hardware processor to input a set of geometric parameters for an electric motor design to a first machine learning model and output, from the first machine learning model, an encoding of the set of geometric parameters, and input a control waveform and the encoding of the set of geometric parameters to a second machine learning model and output, from the second machine learning model, a performance of the electric motor design under a variety of operating conditions and using the control waveform.

The foregoing summary is not intended to be limiting. Moreover, various aspects of the present disclosure may be implemented alone or in combination with other aspects.

### BRIEF DESCRIPTION OF FIGURES

Various aspects and embodiments will be described with reference to the following figures. It should be appreciated that the figures are not necessarily drawn to scale. Items appearing in multiple figures are indicated by the same or a similar reference number in all the figures in which they appear.

FIG. 1 is an illustration of an example machine learning based electric motor design system implemented at least in part by example electric motor design identification software, an example electric motor design image processing service, and an example electric motor design evaluation service, in accordance with some embodiments of the technology described herein.

FIG. 2 is a block diagram of the electric motor design identification software of FIG. 1, which is configured to orchestrate the identification of one or more electric motor designs in accordance with electric motor requirements, in accordance with some embodiments of the technology described herein.

FIG. 3 is a block diagram of an example implementation of the electric motor design image processing service of FIG. 1, which is configured to generate image(s) of variation(s) of an input electric motor design, in accordance with some embodiments of the technology described herein.

FIG. 4 is a block diagram of the electric motor design evaluation service of FIG. 1, which is configured to train an emulator module for machine learning inference operations, in accordance with some embodiments of the technology described herein.

FIG. 5 depicts the block diagram of the electric motor design evaluation service of FIG. 4 generating a performance evaluation of an input electric motor design, in accordance with some embodiments of the technology described herein.

FIG. 6 depicts the block diagram of the electric motor design evaluation service of FIG. 4 generating performance evaluations for reference electric motor designs, in accordance with some embodiments of the technology described herein.

FIG. 7A depicts an example workflow of generating simulated metrics of an electric motor design using electric motor simulation software, in accordance with some embodiments of the technology described herein.

FIG. 7B depicts an example workflow of characterizing a plurality of electric motor designs using the electric motor design evaluation service of FIG. 1, in accordance with some embodiments of the technology described herein.

FIG. 8 depicts a plot including an example Pareto front that is generated using example performance evaluations for a plurality of electric motor designs, in accordance with some embodiments of the technology described herein.

FIG. 9 depicts a selection of an example electric motor design from the Pareto front of FIG. 8, in accordance with some embodiments of the technology described herein.

FIG. 10A depicts example predicted and simulated metrics for a first electric motor design, in accordance with some embodiments of the technology described herein.

FIG. 10B depicts example predicted and simulated metrics for a second electric motor design, in accordance with some embodiments of the technology described herein.

FIG. 11 depicts an example workflow to assemble and/or manufacture an electric vehicle using an identified electric motor design, in accordance with some embodiments of the technology described herein.

FIG. 12 is a flowchart representative of an example process that may be performed and/or example machine-readable instructions that may be executed by processor circuitry to implement at least the electric motor design identification software of FIG. 1 to output at least one proposed electric motor design based on performance evaluations, in accordance with some embodiments of the technology described herein.

FIG. 13 is a flowchart representative of an example process that may be performed and/or example machine-readable instructions that may be executed by processor circuitry to implement at least the electric motor design identification software of FIG. 1 to output performance evaluation(s) of electric motor design(s), in accordance with some embodiments of the technology described herein.

FIG. 14 is an example electronic platform structured to execute the machine-readable instructions of FIGS. 12 and/or 13 to implement the electric motor design identification software of FIGS. 1 and/or 2, in accordance with some embodiments of the technology described herein.

FIG. 15 is an example electronic platform structured to execute the machine-readable instructions of FIGS. 12 and/or 13 to implement the electric motor design image processing service of FIGS. 1 and/or 3, in accordance with some embodiments of the technology described herein.

FIG. 16 is an example electronic platform structured to execute the machine-readable instructions of FIGS. 12 and/or 13 to implement the electric motor design evaluation service of FIGS. 1, 4, 5, and/or 6, in accordance with some embodiments of the technology described herein.

### DETAILED DESCRIPTION

The present application generally provides techniques for designing an electric motor by characterizing a performance for respective ones of a plurality of electric motors under a variety of operating conditions using machine learning. For example, a performance of an electric motor may be represented by a value of an electric motor metric, such as core loss or torque, depending on an angular velocity and/or input current of the electric motor.

The techniques disclosed herein include execution of a machine learning model to process an electric motor design and/or associated electric motor design requirements as input to generate a geometry encoding of the input as output. The geometry encoding can be input into another machine learning model to generate predicted control waveforms as output. The predicted control waveforms may be used for control of an electric motor having the input electric motor design. The techniques disclosed herein include characterizing a performance of the electric motor design under a variety of operating conditions by generating electric motor metrics, such as torque and flux linkage, in accordance with controlling the electric motor design under the variety of operating conditions with the predicted control waveforms.

Advantageously, the techniques disclosed herein can be used to characterize a performance of a plurality of electric motor designs (e.g., 100, 1000, 10,000, 100,000, etc., electric motor designs) substantially in parallel and, from which, at least one electric motor design can be selected that optimizes and/or otherwise satisfies the electric motor design requirements. The at least one electric motor design may be selected for assembly and/or manufacturing for a particular application or use case, such as, for example, inclusion in an electric vehicle.

The terms “simultaneously”, “substantially simultaneously”, and “in parallel” may refer to occurrence in a near instantaneous manner recognizing there may be real-world delays for computing time, transmission, etc. For example, the techniques disclosed herein may characterize the performance of the plurality of electric motor designs within 30 seconds, 10 seconds, 1 second, 500 milliseconds, 100 milliseconds, 10 milliseconds, etc., of real time.

Electric motors are devices that convert electrical energy to mechanical energy, which typically takes the form of rotational motion. Electric motors convert electrical energy to mechanical energy through electromagnetics such as through the interaction of the electric motor's magnetic field and electric current in a wound wire to generate force that generates torque applied on the electric motor's shaft, which transfers energy as the shaft rotates. Typical electric motors include mechanical components such as a stator, which is fixed, and a rotor, which moves. Typical electric motors also include electrical components such as magnets (e.g., electromagnets or permanent magnets) and an armature, which includes the winding (e.g., wound wire on a ferromagnetic core). Together, the magnets (that may also be referred to as “field magnets”) and the armature form a magnetic circuit. Some electric motors attach the winding to the stator and the permanent magnets to the rotor such that the wires in the winding do not have to move as the rotor rotates. Other configurations exist such as the winding being attached to the rotor.

Electric motors may be driven by direct current (DC) supplies, such as from batteries or rectifiers, or by alternating current (AC) supplies, such as a power grid, electric generator, or inverter. In operation, voltage from a supply (e.g., an AC supply, a DC supply) is applied to field magnets of an electric motor, which causes the field magnets to produce a magnetic field that passes through the winding of the electric motor. The produced magnetic field applies a force on the rotor by inducing current to flow through the winding and thereby cause the rotor to rotate and supply a mechanical output. For example, the rotor may be coupled to one or more gears of an electric vehicle, and rotation of the rotor rotates the tires of the electric vehicle.

Typically, a motor controller controls an electric motor using control waveforms. In some applications, a control waveform may be implemented by a continuous function of current against time in each winding phase. For example, the motor controller may be configured to regulate motor speed, torque, and/or power output by changing the magnitude of the input current to the electric motor.

In some applications, a control waveform may be implemented at least in part by varying a frequency of power provided to the electric motor. For example, the motor controller may be configured to regulate motor speed, torque, and/or power output by changing the frequency of the input power to the electric motor. Additionally and/or alternatively, the control waveforms may be implemented by varying an amplitude and/or phase of the input power.

The inventors have recognized that conventional techniques for designing an electric motor for production (e.g., assembly and/or manufacturing of an electric motor for electric vehicle use) is a significant technological undertaking that involves substantial time and hardware computational costs. Conventional techniques for designing an electric motor for production involve a multi-level simulation approach that is computationally inefficient.

By way of example, at a first level of the multi-level simulation approach, an electric motor designer (e.g., an engineer, a scientist, a technician) may select an electric motor design for evaluation. An electric motor design may include geometric parameters (e.g., length, width, height, depth, weight, thickness) of one or more electric motor components, such as the bearings, stator, and/or rotor of an electric motor. The electric motor designer may evaluate and/or measure the electric motor design's performance under a relatively small sampling of operating conditions (e.g., electric motor states) using computationally intensive simulation software.

Conventional simulation software may use finite element analysis (FEA) to model and/or simulate electric motor performance. For example, conventional simulation software may use a digital model (e.g., a computer-aided design (CAD) model) of an electric motor's geometry to apply 3-phase currents to the stator windings in the digital model over a range of frequencies to output simulation results. The simulation results may include an evaluation of the flux linkage of one phase for each simulation run and performing a regression analysis to output the parameter values. The simulation may be repeated for each phase. However, using such simulation software to evaluate a single electric motor design can consume a substantial amount of hardware computational resources, such as processing power, memory, mass storage, and network bandwidth.

Furthering the example, at a second level of the multi-level simulation approach, the electric motor designer may create a simulation model using the results of the single electric motor design to extrapolate simulations of similar, but different electric motor designs. The electric motor designer may use the simulation model to evaluate a relatively low number of electric motor design variations (e.g., 5 electric motor designs, 10 electric motor designs, 20 electric motor designs) and select one of which for production.

However, the inventors have recognized that the conventional multi-level simulation approach is not technologically feasible to evaluate a substantial number of electric motor designs and/or electric motor designs that are substantially different from each other. Specifically, the inventors have recognized that performing multiple simulations on the same electric motor design to simulate performance under a relatively small number of operating conditions using computationally intensive simulation software is not scalable when the number of electric motor designs to be evaluated numbers in the thousands, tens of thousands, etc., and a wide range of operating conditions is to be evaluated.

The inventors have also recognized that the aforementioned simulation model is not configured to evaluate substantially different electric motor designs because the simulation model is built using simulation results from a particular design and used to evaluate similar designs. Put another way, using a simulation model based on one type of electric motor design to simulate performance of a substantially different type of electric motor design produces inaccurate and/or otherwise unusable results. Thus, repetitive simulation efforts may be needed to build a number of simulation models commensurate in scope with a number of the different types of electric motor designs to be evaluated.

The inventors have developed technology to characterize the performance of a plurality of electric motor designs using machine learning to overcome the aforementioned technological challenges of using conventional simulation techniques. The inventors have recognized that conventional simulation techniques are computationally constrained and unscalable. The inventors have recognized that, with the advent of hardware specifically designed to implement machine learning techniques with increased computational efficiency and scalability, the paradigm in designing electric motors has shifted from manually evaluating a relatively small number of electric motor designs to evaluating thousands or tens of thousands of electric motor designs substantially in parallel as disclosed herein.

Specifically, the inventors have developed techniques to map input geometric parameters to at least one electric motor design, such as a plurality of electric motor designs. The techniques developed by the inventors include characterizing a performance of the electric motor designs using machine learning. For example, the techniques may include inputting the plurality of electric motor designs to at least one machine learning model and outputting, from the at least one machine learning model, performance evaluations for the plurality of electric motor designs under a variety of operating conditions. In such an example, the machine learning model(s) is/are trained to generate the performance evaluations in accordance with control waveforms for the plurality of electric motor designs.

In some embodiments, an input electric motor design may be processed to generate and/or identify a plurality of variations (e.g., geometric variations) of the input electric motor design. For example, an input electric motor design may include a plurality of geometric parameters and additional electric motor designs may be identified by varying one(s) of the geometric parameters.

In some embodiments, an optimized control waveform may be identified using machine learning. For example, the techniques may involve predicting, using at least one machine learning model, control waveforms to operate and/or otherwise control the different electric motor designs to meet, satisfy, and/or optimize a set of control waveform requirements. The techniques developed by the inventors may include evaluating respective performances of the different electric motor designs using the control waveforms under a variety of operating conditions. At least one of the different electric motor designs may be selected based on which of the electric motor design(s) have corresponding performances that meet, satisfy, and/or optimize the electric motor requirements.

The inventors have developed techniques that include, in some embodiments, electric motor design identification software that can be configured to ingest an input electric motor design and/or electric motor requirements for evaluation. In some embodiments, the input electric motor design may include geometric parameters, which may be used to identify other electric motor designs. The electric motor requirements may include a set of performance constraints and/or a set of control constraints.

Example performance constraints include minimizing and/or maximizing an electric motor metric. Examples of metrics (e.g., electric motor metrics) include flux linkage, loss, magnetic energy, magnetic co-energy, mechanical displacement, mechanical stress, torque, and torque ripple. By way of example, a performance constraint may be minimization of torque ripple. In such an example, the electric motor design identification software may select an electric motor design that minimizes torque ripple.

Flux linkage (may also be referred to as magnetic flux linkage) in an electric motor refers to the linking of the magnetic field with the conductors of a coil when the magnetic field passes through the loops of the coil. For example, flux linkage can represent the strength of the magnetic field between an electric motor's stator and rotor and thereby creates mechanical torque on the rotor shaft. Flux linkage is useful in characterizing an electric motor because since it is described by Faraday's law of induction, which states that the time variation of flux linkage induces voltage, flux linkage can be used to estimate the back EMF and torque constants of an electric motor, which can accurately replicate the electric motor's behavior in simulation.

Magnetic energy refers to the energy stored in the magnetic field of a magnet, and is used to convert electrical energy into mechanical energy. The magnetic field from magnets in an electric motor creates rotation, which can then be used to power other components. Magnetic co-energy is a non-physical quantity useful for simulation of an electric motor, such as simulating an electric motor using FEA. Magnetic co-energy is useful in calculating magnetic forces and torque in rotating machines, such as electric motors.

Torque is the rotational force that an electric motor creates. Torque ripple is the periodic fluctuation (e.g., a periodic increase or decrease) in output torque of an electric motor as the electric motor shaft rotates. Typically, torque ripple is measures as the difference in maximum and minimum torque over one complete revolution and generally expressed as a percentage. Torque ripple can have undesirable effects on electric motors, such as causing undesirable acoustic noise and vibration.

Examples of loss include alternating current (AC) loss, core loss (and may be referred to as iron loss), mechanical loss, ohmic loss, stray loss, and windage loss. By way of example, AC loss refers to loss that is caused by the time-varying magnetic fields that electric machine windings experience. These fields create a non-uniform current distribution, which results in an increase in total loss due to the non-linear variation in Ohmic loss with current density. Core loss refers to the energy loss that occurs in the iron core of an electric motor. Core loss can be caused by the alternating magnetic field in the core and is a type of constant loss, which can be independent of the electric motor's load and speed. Mechanical losses occur due to friction and windage in an electric motor. For example, friction losses occur due to the movement of the rotor shaft and bearings, and windage losses occur due to the resistance of the air around the rotor. Ohmic loss is a type of energy loss that occurs in electric motors when an electric current flows through the motor's conductors. Stray losses in electric motors are losses that occur due to parasitic effects such as electromagnetic interference (EMI), harmonics, and magnetic fields.

Example control constraints include limits on current magnitude, torque, and voltage. For example, a control constraint may be a current magnitude (e.g., a maximum current magnitude). In such an example, the electric motor design identification software may select an electric motor design to be controlled with control waveforms such that the current magnitude is not exceeded.

In some embodiments, the electric motor design identification software can be configured to identify geometric parameters. For example, the electric motor design identification software may receive an electric motor design. In such an example, the electric motor design identification software may process the electric motor design into geometric parameters.

In some embodiments, the electric motor design identification software can be configured to generate, using an electric motor design image processing service, a plurality of parametric variations, such as changes to geometric parameters of an electric motor design. For example, the electric motor design image processing service can be configured to generate variations of the input electric motor design by varying different geometric parameters of the input electric motor design. In some such embodiments, the variations of the input electric motor design can include free-form shapes of electric motor components, which can have unexpected and/or improved performance with respect to components having regular or conventional contours, curves, and/or shapes.

In some embodiments, the electric motor design image processing service can be configured to convert the variations of the electric motor design into representations that can be ingested by a machine learning model. For example, the electric motor design image processing service can be configured to convert the electric motor design variations into respective image representations. Example image representations include pictures, point clouds, mesh models, and CAD models. Additionally and/or alternatively, the electric motor design variations may be geometric parameters that can be provided directly to a machine learning model without being converted into an image representation.

In some embodiments, the electric motor design identification software can be configured to generate, using an electric motor design evaluation service, a performance evaluation for an electric motor design under a variety of operating conditions. For example, the electric motor design identification software can generate, using at least one machine learning model, a performance evaluation for the electric motor design. In such an example, the electric motor design may be an image representation of the electric motor design or geometric parameters of the electric motor design. For example, the electric motor design identification software can generate, by processing the geometric parameters using at least one machine learning model, a performance evaluation for the electric motor design.

In some embodiments, the electric motor design identification software can be configured to generate, using an electric motor design evaluation service, performance evaluations for a variation of an electric motor design under a variety of operating conditions. For example, the electric motor design identification software can generate, using at least one machine learning model, a performance evaluation of an electric motor design variation. In such an example, the electric motor design variation may be an image representation of a variation of the electric motor design or variations of geometric parameters of the electric motor design. For example, the electric motor design identification software can generate, by processing the geometric parameter variations using at least one machine learning model, a performance evaluation for the electric motor design variation.

Operating conditions may be motor states (e.g., electric motor states). Examples of a motor state include a phase current, a rotor angle, a motor rotational speed, a motor temperature, and a power supply state (e.g., a battery state). Examples of a battery state include state-of-charge, state-of-health, and a battery charge level.

In some embodiments, the performance evaluations can be based on predicted metrics of an electric motor design under a variety of operating conditions. The predicted metrics may characterize the electromechanical behavior of the electric motor design under the variety of operating conditions. Examples of predicted metrics include flux linkage, magnetic energy, magnetic co-energy, torque, and torque ripple. In some such embodiments, the electric motor design evaluation service can output performance evaluations for the electric motor design (and/or variation(s) thereof) using the predicted metrics.

In some embodiments, the electric motor design evaluation service can generate the performance evaluations by using separable machine learning networks. By way of example, the electric motor design evaluation service can input geometric parameters of an electric motor design into a first machine learning model trained to output an encoding (e.g., a geometry encoding) of the geometric parameters.

Furthering the example, the electric motor design evaluation service can input the encoding and a control waveform to control the electric motor design into a second machine learning model trained to generate a performance of the electric motor design having the geometric parameters and being controlled with the control waveform as output. The electric motor design evaluation service can emulate control of the electric motor design using the control waveform to output the predicted metrics, which can be used to generate the performance evaluation of the electric motor design. The electric motor design evaluation service can output the performance evaluation of the electric motor design to the electric motor design identification software.

Beneficially, the separable machine learning networks (e.g., the first and second machine learning networks) improve the computational efficiency of generating a performance evaluation for a plurality of electric motor designs. For example, the first machine learning model can be trained to encode geometric parameters and the second machine learning model can be trained to predict performance of an electric motor design having the geometric parameters. In such an example, the first machine learning model may be executed once to generate an encoding of the geometric parameters and the second machine learning model may be iteratively executed to determine the performance evaluation. In such an example, encoding the geometric parameters is substantially more computationally expensive compared to determining the performance evaluation. For example, the first machine learning model may have a first number of machine learning parameters (e.g., weights, layers) and the second machine learning model may have a substantially smaller second number of machine learning parameters (e.g., weights, layers). Beneficially, by separating the encoding from the performance prediction, the second machine learning model can generate outputs in less time and with fewer hardware computational resources with respect to using a single machine learning model to encode and predict performance. Further, separating the machine learning models achieves improvements in the functioning of a computer that executes the first and/or second machine learning models because the second machine learning model is configured to generate the outputs in less time and with fewer hardware computational resources of the computer with respect to the computer generating the outputs with a single machine learning model.

In some embodiments, the electric motor design identification software can select, using the performance evaluations, at least one electric motor design that meets (e.g., satisfies) and/or exceeds the electric motor requirements. For example, the electric motor design identification software can compare the performance evaluations for the plurality of evaluated electric motor designs. In some such embodiments, the electric motor design identification software can generate a Pareto front using the performance evaluations and select at least one electric motor design from the Pareto front.

In some embodiments, the electric motor design identification software can output the at least one electric motor design for use in a particular application or use case. By way of example, the electric motor design identification software can output an electric motor design having a set of geometric parameters and meeting a set of input electric motor requirements. A physical electric motor can be assembled, constructed, and/or manufactured in accordance with the electric motor design. The physical electric motor can be assembled and/or integrated into a larger sub-assembly, such as an electric vehicle motor compartment, or a larger assembly, such as an electric vehicle. In some embodiments, the electric vehicle can be controlled and/or operated in accordance with the predicted control waveforms output from the electric motor design evaluation service to achieve optimized and/or otherwise improved performance to meet and/or satisfy associated electric motor requirements.

Advantageously, the techniques developed by the inventors overcome the technological challenges of using conventional simulation techniques. First, the electric motor design evaluation service can characterize a performance of an electric motor design in less time and with fewer computational hardware resources with respect to simulating electric motor performance using computationally intensive simulation software. For example, by using separable machine learning networks, a larger machine learning model (e.g., a machine learning model with an increased number of layers) can be run a fewer number of times (e.g., once) than a smaller machine learning model (e.g., a machine learning model with a decreased number of layers) to iterate to achieve a desired outcome with improved speed and reduced physical hardware resource consumption with respect to iteratively executing the larger machine learning model exclusively. In such an example, improvements in the functioning of a computer can be achieved by using separable machine learning networks.

Second, the electric motor design evaluation service can characterize a performance of a substantially greater number of electric motor designs than technologically and/or practically feasible with conventional simulation software. For example, the electric motor design evaluation service can characterize a performance of 100, 1000, 10,000, etc., different electric motor designs substantially in parallel with respect to, for example, sequentially evaluating 10 different electric motor designs using conventional simulation software. In some examples, a single FEA simulation to characterize a performance of an electric motor design can take approximately 0.1 seconds to complete while the electric motor design evaluation service can take approximately 10 microseconds to characterize a performance of the same electric motor design, which represents a 10,000 times speedup in computational efficiency. Further, with this achieved speedup, the electric motor design evaluation service can characterize substantially more electric motor designs in the same time period that FEA simulation software characterizes only a single electric motor design.

Third, the electric motor design evaluation service can characterize a plurality of electric motor designs of which at least some can be substantially different from each other. For example, the electric motor design evaluation service can characterize a first electric motor design having regular contours and a second electric motor design having one or more free-form shapes, which are typically more difficult to evaluate and may not be evaluated at all using conventional electric motor design techniques.

Beneficially, the electric motor design identification software, the electric motor design evaluation service, and the electric motor design image processing service are technological solutions to the aforementioned technological problems. Further, they alone or in combination with one(s) of each other solve these technological problems in the practical application of analyzing the performance of electric motor designs under a variety of operating conditions and/or generating new electric motor designs with improved performance with respect to conventional electric motor designs. Within this practical application, they alone or in combination with one(s) of each other achieve improvements in the functioning of a computer, such as a computer that executes the machine learning models (e.g., the separable machine learning networks) described herein. For example, the electric motor design evaluation service can generate performance evaluations of a substantial number of electric motor designs in less time and with fewer computational hardware resources with respect to the computer executing simulations of the same electric motor designs. In such an example, the electric motor design evaluation service can generate the performance evaluations quicker and with fewer resources because of the use of separable machine learning networks as described above. For example, by configuring a larger machine learning model to be executed a fewer number of times (e.g., once) than a smaller machine learning model to determine a performance evaluation under a variety of operating conditions and with improved speed and reduced physical hardware resource consumption with respect to iteratively executing the larger machine learning model exclusively.

Additionally, the electric motor design identification software, the electric motor design evaluation service, and/or the electric motor design image processing service achieve(s) improvements in the technological field of electric motor design analysis. For example, by shifting the paradigm from simulations using conventional techniques (e.g., FEA) to generating performance evaluations using predicted metrics from trained machine learning models, the techniques described herein solve the aforementioned technological problems and in a manner that improves the technological field as a whole. In such an example, evaluating a substantial number of electric motor designs is technologically impractical but for the advent of advanced machine learning techniques, distributed processing techniques, and computationally efficient machine learning hardware as described herein.

The techniques described herein may be implemented in any of numerous ways, as the techniques are not limited to any particular manner of implementation. Examples of details of implementation are provided herein solely for illustrative purposes. Furthermore, the techniques disclosed herein may be used individually or in any suitable combination, as aspects of the technology described herein are not limited to the use of any particular technique or combination of techniques.

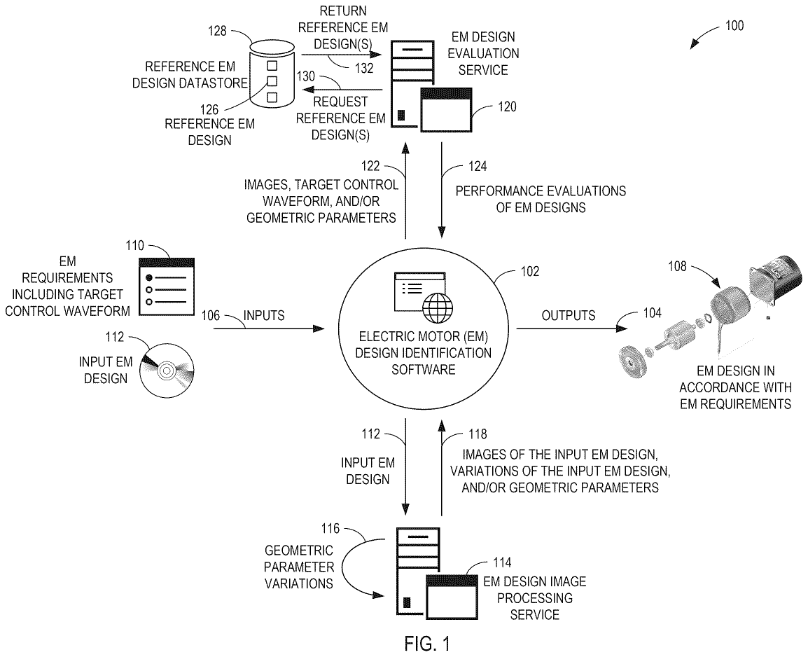

Turning to the figures, the illustrated example of FIG. 1 depicts an example electric motor design system 100 configured with electric motor design identification software 102 to generate one or more electric motor outputs 104 in accordance with one or more electric motor inputs 106. The electric motor design system 100 may be a machine learning based electric motor design system by generating and/or identifying an electric motor design 108 as at least part of the outputs 104 using at least one machine learning model and/or, more generally, machine learning techniques.

The electric motor design system 100 includes the electric motor design identification software 102 to ingest the inputs 106 to provide the outputs 104. The inputs 106 of this example include electric motor requirements 110 and an input electric motor design 112.

In some embodiments, the electric motor requirements 110 represent and/or include performance constraints to be met and/or satisfied by an electric motor design. Example performance constraints include minimization and/or maximization of an electric motor metric. Examples of metrics (e.g., electric motor metrics) include flux linkage, loss (e.g., alternating current loss, core loss), magnetic energy, magnetic co-energy, mechanical displacement, mechanical stress, torque, and torque ripple. For example, a performance constraint may be minimization of torque ripple. For example, a performance constraint for an electric motor design may be minimization of torque ripple, such that an electric motor design output from the electric motor design identification software 102 minimizes torque ripple. In another example, a performance constraint for an electric motor design may be maximizing torque, such that an electric motor design output from the electric motor design identification software 102 maximizes torque.

Additionally and/or alternatively, the electric motor requirements 110 may represent and/or include control constraints to be met and/or satisfied by control of the electric motor design. Example control constraints include limits (e.g., bounds, restrictions, thresholds) on current magnitude, torque, and voltage. For example, a control constraint for an electric motor design may be a maximum current magnitude, such that control of the electric motor design does not exceed the maximum current magnitude.

In the shown example, the control constraints are implemented by a target control waveform. For example, the target control waveform may be a waveform shaped by the control constraints. In such an example, the target control waveform may be a waveform shaped by at least one of a minimum and/or maximum input voltage, a minimum and/or maximum torque, or a minimum and/or maximum current magnitude.

The inputs 106 of this example also include the input electric motor design 112. In some embodiments, the input electric motor design 112 is an electric motor design whose performance is to be evaluated under a variety of operating conditions. In some embodiments, the input electric motor design 112 is an electric motor design having a first type to which the electric motor design identification software 102 is to identify electric motor design(s) of a second type to be evaluated under a variety of operating conditions. In some such embodiments, the electric motor design identification software 102 may determine whether a different electric motor design may better meet the electric motor requirements 110 with respect to the input electric motor design 112.

The input electric motor design 112 of the shown example is a digital representation of an electric motor design. The digital representation may be an image representation. Examples of an image representation include a picture, a point cloud, a mesh model, and a computer-aided design (CAD) model. For example, the input electric motor design 112 may be a CAD model of a design of an electric motor.

Additionally and/or alternatively, the input electric motor design 112 may be one or more geometric parameters of an electric motor design. For example, the input electric motor design 112 may be implemented by a set of geometric parameters.

In the illustrated example, the electric motor design identification software 102 processes, by using an electric motor design image processing service 114, the inputs 106, or portion(s) thereof, into variations of the input electric motor design 112. For example, the electric motor design identification software 102 receives the inputs 106 and determines to provide at least a portion of the inputs 106, such as the input electric motor design 112, to the electric motor design image processing service 114.

The electric motor design image processing service 114 of the shown example is configured to process an electric motor design into a format and/or representation for ingestion by at least one machine learning model. For example, the electric motor design image processing service 114 can receive a CAD model of the input electric motor design 112 from the electric motor design identification software 102. In such an example, the electric motor design image processing service 114 can convert the CAD model into an image (e.g., a two-dimensional (2-D) image) of the input electric motor design 112 for output to the electric motor design identification software 102.

Additionally and/or alternatively, the electric motor design image processing service 114 may receive the input electric motor design 112 as implemented by geometric parameter(s). The electric motor design image processing service 114 can convert the geometric parameter(s) into an image (e.g., a two-dimensional (2-D) image) of the geometric parameter(s) for output to the electric motor design identification software 102. Alternatively, the electric motor design image processing service 114 may not convert the geometric parameter(s) into an image such that the geometric parameter(s) may be provided to the electric motor design evaluation service 120.

In some embodiments, the electric motor design image processing service 114 can be configured to generate and/or identify variations of the input electric motor design 112. For example, the electric motor design image processing service 114 can identify a geometric parameter of the input electric motor design 112, such as a length, width, height, depth, weight, and/or thickness of a rotor of the input electric motor design 112. In another example, the geometric parameter may be an air gap or spacing between the rotor and a stator of the input electric motor design 112. In some such embodiments, the electric motor design image processing service 114 can generate variation(s) of the geometric parameter shown as geometric parameter variations 116. For example, the electric motor design image processing service 114 can increase the length of the rotor and/or decrease the air gap between the rotor and the stator.

In some embodiments, the electric motor design image processing service 114 can be configured to provide outputs 118 to the electric motor design identification software 102. In some embodiments, the outputs 118 are images. The images may represent digital representations of electric motor designs. For example, the images may include an image of the input electric motor design 112.

In some embodiments, the outputs 118 may be images of variations of the input electric motor design 112. For example, the electric motor design image processing service 114 can output a first image of the input electric motor design 112, which includes a rotor of the input electric motor design 112 having a first rotor length. In such an example, the electric motor design image processing service 114 can output a second image of the input electric motor design 112 having a second rotor length different from the first rotor length. In some embodiments, the second image may also include variations of one or more other geometric parameters, such as having a different rotor/stator air gap with respect to the input electric motor design 112. For example, the second image may include one or more geometric parameters that are different from the input electric motor design 112.

In some embodiments, the outputs 118 are a set of geometric parameters of an electric motor design. For example, the electric motor design image processing service 114 can be configured to output a set of geometric parameters of an electric motor design to the electric motor design identification software 102.

In the illustrated example, the electric motor design identification software 102 processes, using an electric motor design evaluation service 120, inputs 122 into performance evaluations 124 of one or more electric motor designs. In some embodiments, the inputs 122 are one or more of the images from the electric motor design image processing service 114. Additionally and/or alternatively, the inputs 122 may include the target control waveform of the electric motor requirements 110. Additionally and/or alternatively, the inputs 122 may include geometric parameters, such as geometric parameters of the input electric motor design 112. By way of example, the inputs 122 may include an image of the input electric motor design 112, one or more images of variations of the input electric motor design 112, the target control waveform, and/or a set of geometric parameters.

Additionally and/or alternatively, the electric motor design evaluation service 120 may output the performance evaluations 124 using a different electric motor design representation as input, such as textual representation or a tabular representation (e.g., one or more tables including text and/or numbers). For example, the inputs 122 may additionally and/or alternatively include one or more tables (e.g., tabular data) representative of one or more geometric parameters and/or, more generally, of one or more electric motor designs.

As shown, the performance evaluations 124 are for electric motor designs. For example, the electric motor design evaluation service 120 may generate and/or output one of the performance evaluations 124 for each electric motor design under evaluation. In some such examples, the electric motor design evaluation service 120 may process an image of an electric motor design into a performance evaluation of the electric motor design. In some examples, the electric motor design evaluation service 120 may process geometric parameters of an electric motor design into a performance evaluation of the electric motor design.

In some embodiments, the performance evaluations 124 include metrics for electric motor designs under a variety of operating conditions. For example, one of the performance evaluations 124 may be for an electric motor design and include values of flux linkage, magnetic energy, magnetic co-energy, torque, and/or torque ripple for the electric motor design under a variety of operating conditions.

The operating conditions may be motor states (e.g., electric motor states). Examples of a motor state include a phase current, a rotor angle, a motor rotational speed, a motor temperature, and a power supply state (e.g., a battery state). Additionally and/or alternatively, an operating condition may be a combination of motor states. For example, an operating condition may be a value of a phase current, a rotor angle, a value of a motor rotational speed, and/or a motor temperature.

In some embodiments, the electric motor design evaluation service 120 generates the performance evaluations 124 using machine learning. For example, the electric motor design evaluation service 120 can map geometric parameters of an electric motor design and/or an image of an electric motor design to a plurality of electric motor designs; execute one or more machine learning models to generate geometry encodings of the plurality of electric motor designs; predict metrics of the plurality of electric motor designs when controlled by control waveforms; and/or output the performance evaluations 124 using the predicted metrics.

In some embodiments, the electric motor design evaluation service 120 identifies one or more reference electric motor designs 126 using the inputs 122. For example, the electric motor design evaluation service 120 may map geometric parameters to one or more of the reference electric motor designs 126.

The reference electric motor designs 126 may be known geometric parameters, previously generated geometric parameters, electric motor designs, and/or previously generated electric motor designs. For example, the electric motor design evaluation service 120 may determine that one(s) of the reference electric motor designs 126 have a geometric parameter in common with an electric motor design represented by the inputs 122. In such an example, the electric motor design evaluation service 120 may evaluate the one(s) of the reference electric motor designs 126 to determine whether they have improved performance with respect to the electric motor design represented by the inputs 122.

The reference electric motor designs 126 of this example are stored in a reference electric motor design datastore 128. For example, the electric motor design evaluation service 120 may request identified one(s) of the reference electric motor designs 126 from the reference electric motor design datastore 128 via one or more request operations 130. In such an example, the electric motor design evaluation service 120 may receive the requested one(s) of the reference electric motor designs 126 from the reference electric motor design datastore 128 via one or more return operations 132.

In some embodiments, the reference electric motor design datastore 128 can be implemented by any technology for storing data. For example, the reference electric motor design datastore 128 can be implemented by a volatile memory (e.g., a Synchronous Dynamic Random Access Memory (SDRAM), a Dynamic Random Access Memory (DRAM), a RAMBUS Dynamic Random Access Memory (RDRAM), etc.) and/or a non-volatile memory (e.g., flash memory). The reference electric motor design datastore 128 may additionally or alternatively be implemented by one or more double data rate (DDR) memories, such as DDR, DDR2, DDR3, DDR4, DDR5, mobile DDR (mDDR), etc. The reference electric motor design datastore 128 may additionally or alternatively be implemented by one or more mass storage devices such as hard disk drive(s) (HDD(s)), compact disk (CD) drive(s), digital versatile disk (DVD) drive(s), solid-state disk (SSD) drive(s), etc. While in the illustrated example the reference electric motor design datastore 128 is illustrated as a single datastore, the reference electric motor design datastore 128 may be implemented by any number and/or type(s) of datastore. Furthermore, the data stored in the reference electric motor design datastore 128 may be in any data format. Examples of data formats include a flat file, binary data, comma delimited data, tab delimited data, and structured query language (SQL) structures. For example, the reference electric motor design datastore 128 can store the reference electric motor designs 126 as files on a file system indexed by names, contents, and/or directories.

In some embodiments, the reference electric motor design datastore 128 may be implemented by a database system, such as one or more databases. The term “database” as used herein means an organized body of related data, regardless of the manner in which the data or the organized body thereof is represented. For example, the organized body of related data may be in the form of one or more of a table, a log, a map, a grid, a packet, a datagram, a frame, a file, an e-mail, a message, a document, a report, a list, an image, a picture, a point cloud, a mesh model, a CAD model, or in any other form.

In the illustrated example, the electric motor design evaluation service 120 outputs the performance evaluations 124 for a plurality of electric motor designs to the electric motor design identification software 102. In some embodiments, the performance evaluations 124 may be for thousands or tens of thousands of electric motor designs.

Beneficially, in some such embodiments, the electric motor design evaluation service 120 can be configured to generate the performance evaluations 124 for the thousands or tens of thousands of electric motor designs substantially in parallel using physical hardware resources configured to execute and/or instantiate machine learning techniques. Examples of the physical hardware resources include artificial intelligence/machine-learning (AI/ML) processors, application specific integrated circuits (ASICs), field programmable gate arrays (FPGAs), graphics processing units (GPUs), neural network (NN) processors, systems-on-chip (SoCs), vision processing units (VPUs), and any combination(s) thereof.

The electric motor design identification software 102 may use the performance evaluations 124 to select one or more electric motor designs, such as the electric motor design 108, as the outputs 104. For example, the electric motor design identification software 102 may select one or more electric motor designs, such as the electric motor design 108, that meets, satisfies, and/or comports with the electric motor requirements 110.

In some embodiments, the electric motor design identification software 102 may select the input electric motor design 112 as the electric motor design 108. For example, the electric motor design identification software 102 may select the input electric motor design 112 if the input electric motor design 112 meets and/or optimizes the electric motor requirements 110 based on the performance evaluations 124 and with respect to other evaluated electric motor designs, such as one(s) of the reference electric motor designs 126 and/or one(s) of the variations of the input electric motor design 112.

In some embodiments, the electric motor design identification software 102 may select an electric motor design generated and/or identified by the electric motor design system 100 as the electric motor design 108. For example, the electric motor design identification software 102 may select one(s) of the reference electric motor designs 126 and/or one(s) of the variations of the input electric motor design 112 based on the performance evaluations 124.

In some embodiments, one or more portions of the electric motor design system 100 may be implemented by hardware alone, or by a combination of hardware, software, and/or firmware. For example, the electric motor design identification software 102, the electric motor design image processing service 114, and/or the electric motor design evaluation service 120 may be implemented alone, or by a combination of hardware, software, and/or firmware.

In some embodiments, the electric motor design identification software 102 is implemented by one or more servers (e.g., computer servers) accessible via a network (e.g., a computer-implemented network). For example, the electric motor design identification software 102 can be implemented by one or more physical servers and/or virtualizations of the one or more physical servers. In some embodiments, the one or more servers are hosted by a cloud provider (e.g., a public cloud provider, a private cloud provider) and/or an enterprise network.

In some embodiments, the electric motor design image processing service 114 is implemented by one or more servers (e.g., computer servers) accessible via a network (e.g., a computer-implemented network). For example, the electric motor design image processing service 114 can be implemented by one or more physical servers and/or virtualizations of the one or more physical servers. In some embodiments, the one or more servers are hosted by a cloud provider (e.g., a public cloud provider, a private cloud provider) and/or an enterprise network.

In some embodiments, the electric motor design evaluation service 120 is implemented by one or more servers (e.g., computer servers) accessible via a network (e.g., a computer-implemented network). For example, the electric motor design evaluation service 120 can be implemented by one or more physical servers and/or virtualizations of the one or more physical servers. In some embodiments, the one or more servers are hosted by a cloud provider (e.g., a public cloud provider, a private cloud provider) and/or an enterprise network.

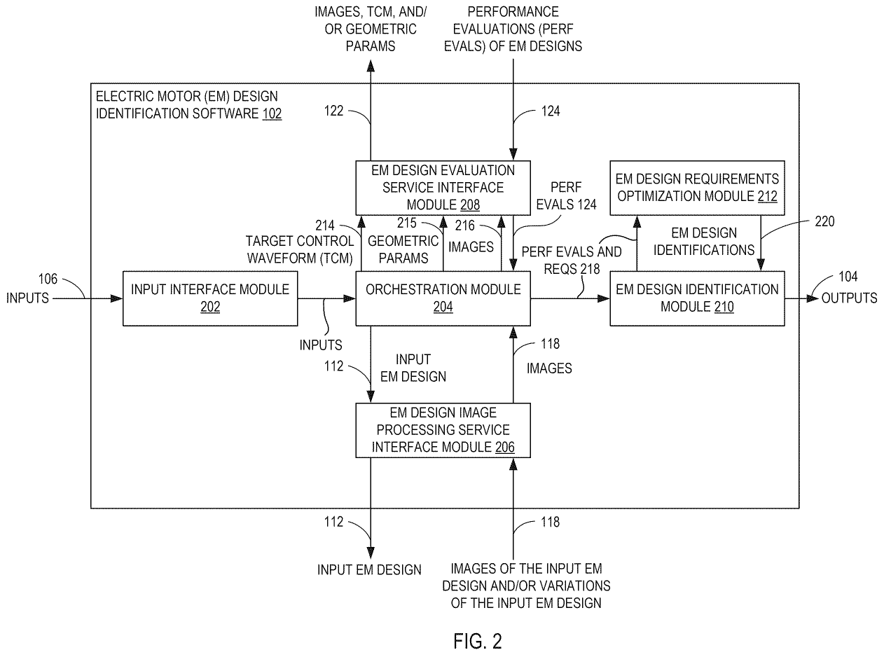

FIG. 2 is a block diagram of the electric motor design identification software 102 of FIG. 1. In some embodiments, the electric motor design identification software 102 can be configured to orchestrate the identification of one or more electric motor designs, such as the electric motor design 108 of FIG. 1, in accordance with the electric motor requirements 110 of FIG. 1. As shown, the electric motor design identification software 102 of the illustrated example includes an input interface module 202, an orchestration module 204, an electric motor image processing service interface module 206, an electric motor evaluation service interface module 208, an electric motor design identification module 210, and an electric motor design requirements optimization module 212.

The input interface module 202 of the illustrated example can be configured to receive the inputs 106 of FIG. 1. For example, the input interface module 202 may be configured to receive the electric motor requirements 110, the input electric motor design 112, and/or a set of geometric parameters of the input electric motor design 112.

In some embodiments, the input interface module 202 may be implemented by one or more interfaces configures to receive and/or transmit data. The interface(s) may be implemented by one or more software interfaces, such as one or more application programming interfaces (APIs). Additionally and/or alternatively, the input interface module 202 may be implemented by one or more interface devices, such as network interface circuitry (e.g., a network interface card (NIC), a smart NIC, etc.), a gateway, a router, a switch, etc., and/or any combination(s) thereof. The interface(s) may implement any type of communication interface, such as BLUETOOTH®, a cellular telephone system (e.g., a 4G LTE interface, a 5G interface, a future generation 6G interface, etc.), an Ethernet interface, a near-field communication (NFC) interface, an optical disc interface (e.g., a Blu-ray disc drive, a Compact Disk (CD) drive, a Digital Versatile Disk (DVD) drive, etc.), an optical fiber interface, a satellite interface (e.g., a beyond-line-of-site (BLOS) satellite interface, a line-of-site (LOS) satellite interface, etc.), a Universal Serial Bus (USB) interface (e.g., USB Type-A, USB Type-B, USB TYPE-C™ or USB-C™, etc.), etc., and/or any combination(s) thereof.

The orchestration module 204 of the illustrated example can be configured to orchestrate the processing of the inputs 106 into the outputs 104. For example, the orchestration module 204 can route the input electric motor design 112 of the inputs 106 to the electric motor design image processing service 114 via the electric motor image processing service interface module 206. In another example, the orchestration module 204 can route a target control waveform 214, which can be included in the electric motor requirements 110 of the inputs 106, to the electric motor design evaluation service 120 via the electric motor evaluation service interface module 208. In yet another example, the orchestration module 204 can route geometric parameters 215 (identified by “GEOMETRIC PARAMS”) of the input electric motor design 112 to the electric motor design evaluation service 120 via the electric motor evaluation service interface module 208.

The electric motor image processing service interface module 206 of the illustrated example can be configured to transmit data to and/or receive data from the electric motor design image processing service 114. For example, the electric motor image processing service interface module 206 can transmit, cause transmission of, and/or otherwise provide the input electric motor design 112, and/or the geometric parameters 215 thereof, to the electric motor design image processing service 114. The electric motor image processing service interface module 206 can be configured to receive the images 118 from the electric motor design image processing service 114, which can include an image of the input electric motor design 112 and/or images of variations of the input electric motor design 112. In response to receiving the images 118, the electric motor image processing service interface module 206 can provide the images 118 to the orchestration module 204. Additionally and/or alternatively, the electric motor image processing service interface module 206 may receive the geometric parameters 215 from the electric motor design image processing service 114.

The electric motor evaluation service interface module 208 of the illustrated example can be configured to transmit data to and/or receive data from the electric motor design evaluation service 120. For example, the electric motor evaluation service interface module 208 can transmit, cause transmission of, and/or otherwise provide one or more images 216 to the electric motor design evaluation service 120. In some embodiments, the one or more images 216 may include an image of the input electric motor design 112 and/or images of variations of the input electric motor design 112.

The electric motor evaluation service interface module 208 can be configured to receive the performance evaluations 124 from the electric motor design evaluation service 120, which can include a performance evaluation of the input electric motor design 112 and/or respective performance evaluation(s) of the image(s) of the variation(s) of the input electric motor design 112. In response to receiving the performance evaluations 124, the electric motor evaluation service interface module 208 can provide the performance evaluations 124 to the orchestration module 204.

The electric motor design identification module 210 of the illustrated example can be configured to process, using the electric motor design requirements optimization module 212, at least one of the performance evaluations 124 or the electric motor requirements 110 of FIG. 1 (collectively referred to as performance evaluations and electric motor requirements 218) into the outputs 104. For example, the electric motor design identification module 210 can receive the performance evaluations and electric motor requirements 218 from the orchestration module 204 and output them to the electric motor design requirements optimization module 212.

The electric motor design requirements optimization module 212 can be configured to compare characterizations of a plurality of electric motor designs using their respective performance evaluations 124. For example, the electric motor design requirements optimization module 212 can determine and/or identify, using the performance evaluations 124, which one(s) of the plurality of electric motor designs meets the electric motor requirements 110 and output the identified one(s) as electric motor design identifications 220. For example, the electric motor design requirements optimization module 212 can generate a Pareto front using the performance evaluations 124 and, from which, the electric motor design requirements optimization module 212 can identify which one(s) of the plurality of electric motor designs from the Pareto front. Alternatively, the electric motor design requirements optimization module 212 may output the Pareto front to the electric motor design identification module 210 such that the electric motor design identification module 210 can output the electric motor design identifications 220.

In some embodiments, the electric motor design identifications 220 include one or more identifiers that respectively identify an electric motor design. For example, the electric motor design identifications 220 may include a first identifier that identifies the input electric motor design 112 of FIG. 1. In another example, the electric motor design identifications 220 may include a second identifier that identifies a variation of the input electric motor design 112 generated by the electric motor design image processing service 114. In yet another example, the electric motor design identifications 220 may include a third identifier that identifies one of the reference electric motor designs 126. In yet another example, the electric motor design identifications 220 may include a fourth identifier that identifies one(s) of the geometric parameters 215. Additionally and/or alternatively, the electric motor design identifications 220 may include the electric motor design, such as an image of the electric motor design.

In some embodiments, the electric motor design identification module 210 outputs one or more of the electric motor design identifications 220 as the outputs 104. Additionally and/or alternatively, the electric motor design identification module 210 may output the electric motor design that meets the electric motor requirements 110, such as an image representation of the electric motor design.

While an example implementation of the electric motor design identification software 102 of FIG. 1 is depicted in FIG. 2, other implementations are contemplated. For example, one or more blocks, components, functions, etc., of the electric motor design identification software 102 may be combined or divided in any other way. The electric motor design identification software 102 of the illustrated example may be implemented by hardware alone, or by a combination of hardware, software, and/or firmware. For example, the electric motor design identification software 102 may be implemented by one or more analog or digital circuits (e.g., comparators, operational amplifiers, etc.), one or more hardware-implemented state machines, one or more programmable processors (e.g., central processing units (CPUs), digital signal processors (DSPs), FPGAs, GPUs, etc.), one or more network interfaces (e.g., network interface circuitry, NICs, smart NICs, etc.), one or more ASICs, one or more memories (e.g., non-volatile memory, volatile memory, etc.), one or more mass storage disks or devices (e.g., hard-disk drives (HDDs), solid-state disk (SSD) drives, etc.), etc., and/or any combination(s) thereof.

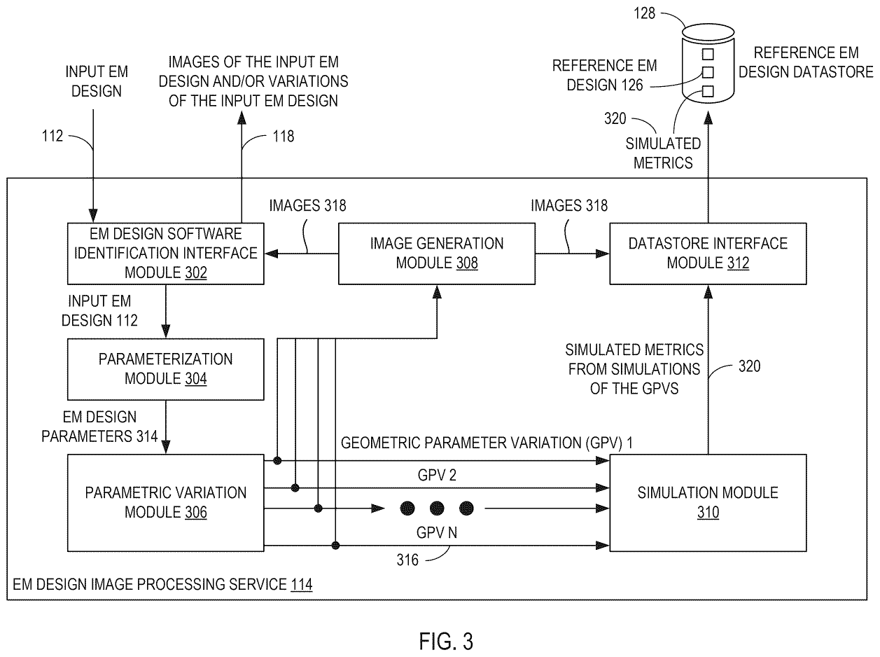

FIG. 3 is a block diagram of an example implementation of the electric motor design image processing service 114 of FIG. 1. In some embodiments, the electric motor design image processing service 114 can be configured to generate an image representation of an electric motor design. In some embodiments, the electric motor design image processing service 114 can be configured to generate one or more geometric parameters of an electric motor design. As shown, the electric motor design image processing service 114 includes an electric motor design software identification interface module 302, a parameterization module 304, a parameter variation module 306, an image generation module 308, a simulation module 310, and a datastore interface module 312.

The electric motor design software identification interface module 302 of the illustrated example can be configured to receive data from the electric motor design identification software 102. For example, the electric motor design software identification interface module 302 can receive the input electric motor design 112 and/or geometric parameters of the input electric motor design 112 from the electric motor design identification software 102.

The electric motor design software identification interface module 302 of the illustrated example can be configured to transmit data to the electric motor design identification software 102. For example, the electric motor design software identification interface module 302 can transmit, cause transmission of, and/or otherwise provide the images 118 and/or geometric parameters to the electric motor design identification software 102.

As shown, the electric motor design software identification interface module 302 can output received data, such as the input electric motor design 112, to the parameterization module 304. Additionally and/or alternatively, the electric motor design software identification interface module 302 may output geometric parameters of the input electric motor design 112 to the parameterization module 304.

The parameterization module 304 of the illustrated example can be configured to process the input electric motor design 112 into electric motor design parameters 314, such as by extracting the electric motor design parameters 314 from and/or based on the input electric motor design 112.

Examples of the electric motor design parameters 314 include geometric parameters of one or more components of the input electric motor design 112. Example geometric parameters include a length, a width, a height, a depth, a weight, and a thickness of a component.

Example components include stationary and moveable components. Example stationary components of an electric motor design include a flange bracket, a motor case, and a stator. Example moveable components of an electric motor design include a bearing, a rotor, and a shaft.

In some embodiments, the parameterization module 304 can generate and/or output the electric motor design parameters 314 using machine learning. For example, the parameterization module 304 can input the input electric motor design 112 into a machine learning model and output from the machine learning model the electric motor design parameters 314. In some embodiments, the machine learning model can be configured to perform machine vision. For example, the machine learning model can be a transformer. An example of a transformer is a vision transformer. Alternatively, the machine learning model may be a feature-based model, a deep learning network, and/or a neural network (e.g., a convolutional neural network (CNN)).

By way of example, the parameterization module 304 can identify, using a machine learning model, one or more components of the input electric motor design 112, such as a flange bracket, a motor case, a stator, a bearing, a rotor, and/or a shaft. Furthering the example, the parameterization module 304 can identify, using the machine learning model, one or more geometric parameters of the one or more identified components. For example, the parameterization module 304 can identify at least one of a length, a width, a height, a depth, a weight, or a thickness of a rotor of the input electric motor design 112.

In the illustrated example, the parameter variation module 306 can receive the electric motor design parameters 314 from the parameterization module 304. The parameter variation module 306 of this example can be configured to process the electric motor design parameters 314 into one or more geometric parameter variations 316 (identified by geometric parameter variation (GPV) 1, GPV 2, GPV N). In some embodiments, the geometric parameter variations 316 include the geometric parameters of the input electric motor design 112. In some embodiments, the geometric parameter variations 316 include variations of the geometric parameters of the input electric motor design 112.

By way of example, the parameter variation module 306 can select a geometric parameter from the electric motor design parameters 314, such as a first length of a rotor of the input electric motor design 112. The parameter variation module 306 can output the first length of the rotor of the input electric motor design 112 to the image generation module 308 as one of the geometric parameter variations 316. The image generation module 308 can convert a plurality of geometric parameters of the input electric motor design 112, which can include the first length of the rotor, into a first image representation of the plurality of geometric parameters and/or, more generally, a first image representation of the input electric motor design 112. The first image representation may be output as one of the images 318.

By way of another example, the parameter variation module 306 can select the length of the rotor of the input electric motor design 112. The parameter variation module 306 can generate one or more variations of the rotor length. For example, the parameter variation module 306 can generate a first geometric parameter variation (e.g., GPV 1) by increasing the rotor length from the first length to a second length, a second geometric parameter variation (e.g., GPV 2) by decreasing the rotor length from the first length to a third length, and so on. The image generation module 308 can convert a plurality of geometric parameters of the input electric motor design 112, which can include the second length of the rotor (e.g., the increased length), into a second image representation of the plurality of geometric parameters and/or, more generally, a second image representation of the input electric motor design 112. Further, the image generation module 308 can convert a plurality of geometric parameters of the input electric motor design 112, which can include the third length of the rotor (e.g., the decreased length), into a third image representation of the plurality of geometric parameters and/or, more generally, a third image representation of the input electric motor design 112.

In this way, the image generation module 308 can generate the images 318 of the input electric motor design 112 and/or variations thereof, which can be output to the electric motor design identification software 102 via the electric motor design software identification interface module 302. Additionally and/or alternatively, the image generation module 308 can output the images 318 for storage in the reference electric motor design datastore 128 as one(s) of the reference electric motor designs 126. In some embodiments, the images 318 may be images of portions of an electric motor design defined by geometric parameters.

As depicted, the parameter variation module 306 can be configured to output the geometric parameter variations 316 to at least one of the image generation module 308 or the simulation module 310. The simulation module 310 of this example can be configured to simulate performance of an electric motor design. For example, the simulation module 310 can be configured to simulate performance of the input electric motor design 112. In another example, the simulation module 310 can be configured to simulate performance of a variation of the input electric motor design 112, such as an electric motor design having one or more of the geometric parameter variations 316.

In some embodiments, the simulation module 310 can be configured to determine and/or output simulated metrics 320 from simulations of electric motor designs having the geometric parameter variations 316. For example, the simulation module 310 can be configured to simulate performance of an electric motor design using finite element analysis (FEA) to output the simulated metrics 320. In such an example, the simulation module 310 can be configured to execute simulation software that performs FEA on an electric motor design to output the simulated metrics 320 for the electric motor design.

The simulated metrics may characterize the electromechanical behavior of the electric motor designs under the variety of operating conditions. Examples of the simulated metrics (e.g., simulated electric motor metrics) include flux linkage, magnetic energy, magnetic co-energy, torque, and torque ripple. For example, the simulation module 310 can simulate a performance of an electric motor design using FEA to output values of flux linkage, magnetic energy, magnetic co-energy, torque, and torque ripple under a variety of operating conditions.

In some embodiments, the simulation module 310 determines the simulated metrics 320 such that they can be used as training data for a machine learning model. For example, the electric motor design evaluation service 120 of FIG. 1 can train one or more machine learning models to output the performance evaluations 124 using the simulated metrics 320.

In the illustrated example, the datastore interface module 312 receives the simulated metrics 320 and outputs the simulated metrics 320 to the reference electric motor design datastore 128 for storage. For example, the reference electric motor design datastore 128 can store the simulated metrics 320 in association with their corresponding electric motor design. Additionally and/or alternatively, the datastore interface module 312 may store the simulated metrics 320 in a different datastore (e.g., a metrics datastore, a simulated metrics datastore).

While an example implementation of the electric motor design image processing service 114 of FIG. 1 is depicted in FIG. 3, other implementations are contemplated. For example, one or more blocks, components, functions, etc., of the electric motor design image processing service 114 may be combined or divided in any other way. The electric motor design image processing service 114 of the illustrated example may be implemented by hardware alone, or by a combination of hardware, software, and/or firmware. For example, the electric motor design image processing service 114 may be implemented by one or more analog or digital circuits (e.g., comparators, operational amplifiers, etc.), one or more hardware-implemented state machines, one or more programmable processors, one or more network interfaces, one or more ASICs, one or more memories, one or more mass storage disks or devices, etc., and/or any combination(s) thereof.

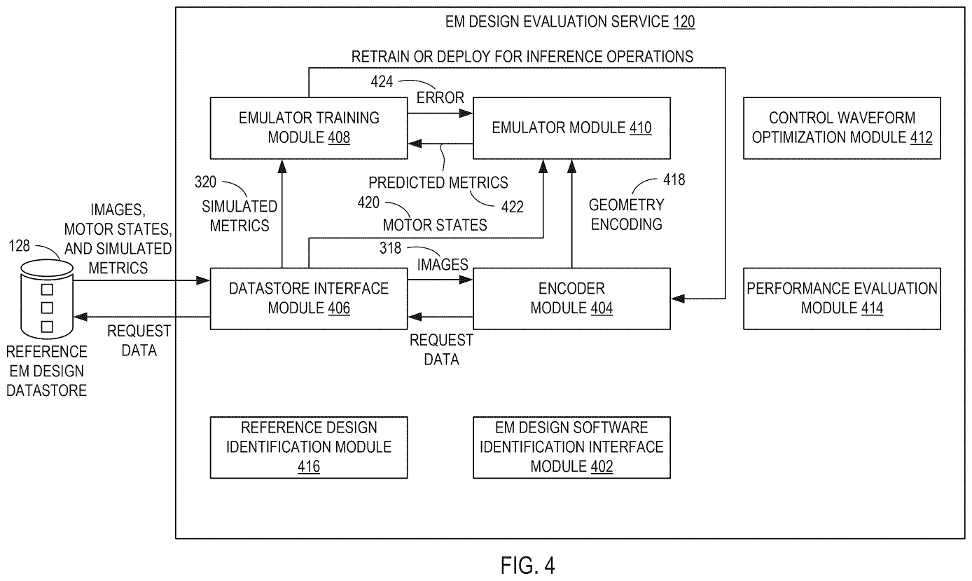

FIG. 4 is a block diagram of the electric motor design evaluation service 120 of FIG. 1. As shown, the electric motor design evaluation service 120 includes an electric motor design software identification interface module 402, an encoder module 404, a datastore interface module 406, an emulator training module 408, an emulator module 410, a control waveform optimization module 412, a performance evaluation module 414, and a reference design identification module 416.

In some embodiments, the electric motor design evaluation service 120 can be configured to train a machine learning model for machine learning inference operations. The machine learning model may be and/or be implemented by the emulator module 410. For example, the emulator module 410 may be and/or be implemented by one or more machine learning models.

The one or more machine learning models may be one or more deep learning models. Examples of a deep learning model include a neural network. Examples of a neural network include an autoencoder, a CNN, a CTC-fitted neural network model, a graph neural network (GNN), a multilayer perceptron, a recurrent neural network (RNN), a generative adversarial network (GAN), and a transformer. For example, the emulator module 410 may be and/or implemented by a multilayer perceptron. Additionally and/or alternatively, the emulator module 410 may be and/or be implemented by a different type of machine learning model, such as a clustering model, a decision tree, a support vector machine (SVM), a Bayesian network, a hidden Markov model, and/or any combination(s) thereof.

In the illustrated example, the electric motor design evaluation service 120 may train the emulator module 410 using geometry encodings 418. For example, the encoder module 404 can be configured to request data (e.g., training data) from the reference electric motor design datastore 128, which can be used for training the machine learning model(s) implemented by the emulator module 410.

In some embodiments, the geometry encodings 418 are encodings of the images 318. In some embodiments, the geometry encodings 418 are encodings of geometric parameters of an electric motor design.

As shown, the encoder module 404 requests data from the reference electric motor design datastore 128 via the datastore interface module 406. The datastore interface module 406 can be configured to transmit data to and/or receive data from the reference electric motor design datastore 128. For example, the datastore interface module 406 can transmit a request (e.g., a query) to the reference electric motor design datastore 128 for data stored therein.

The requested data may include one or more of the images 318, which can correspond to one or more respective electric motor designs. The requested data may include the simulated metrics 320 that correspond to the one or more images 318. For example, the simulated metrics 320 can correspond to the one or more respective electric motor designs. The requested data may include one or more geometric parameters of an electric motor design, which is not shown but is contemplated by the inventors.

The requested data may include one or more motor states 420. Examples of the motor states 420 include a phase current, a rotor angle, a motor rotational speed, and a motor temperature, and/or any combination(s) thereof.

As depicted and responsive to the request for data, the reference electric motor design datastore 128 returns one(s) of the images 318, the simulated metrics 320, and the motor states 420 to the datastore interface module 406. Additionally and/or alternatively, the reference electric motor design datastore 128 may return one or more geometric parameters. The datastore interface module 406 can output the one or more images 318 and/or the one or more geometric parameters to the encoder module 404, the simulated metrics 320 to the emulator training module 408, and/or the motor states 420 to the emulator module 410 to effectuate machine learning training of the emulator module 410.

By way of example, the encoder module 404 can convert a first one of the images 318 into the geometry encoding 418 of the first one of the images 318. The geometry encoding 418 may be a numerical representation of the first one of the images 318.

By way of another example, the encoder module 404 can convert a first one of the geometric parameters into the geometry encoding 418. The geometry encoding 418 may be a numerical representation of the first one of the geometric parameters.

Examples of a numerical representation include a dense representation and a sparse representation. The sparse representation may be a high-dimensional sparse representation and the dense representation may be a low-dimensional dense representation.

In some embodiments, the encoder module 404 can be configured to perform machine vision. For example, the encoder module 404 can be and/or be implemented by a machine learning model configured to perform machine vision. The machine learning model may be a transformer. An example of a transformer is a vision transformer. For example, the encoder module 404 can be a vision transformer. Alternatively, the machine learning model may be a feature-based model and/or a deep learning network.

In some embodiments, the encoder module 404 can be trained to encode a fixed set of input geometric parameters of an electric motor design. For example, the encoder module 404 can be trained to encode stationary components of the electric motor design.

As shown, the encoder module 404 outputs the geometry encoding of the first one of the images 318 to the emulator module 410. Alternatively, the encoder module 404 may train the emulator module 410 in batches, such as by converting multiple ones of the images 318 into respective geometry encodings 418 and providing the geometry encodings 418 to the emulator module 410.

Additionally and/or alternatively, the encoder module 404 may output the geometry encoding of the first one of the geometric parameters to the emulator module 410. The encoder module 404 may train the emulator module 410 in batches, such as by converting multiple ones of the geometric parameters into respective geometry encodings 418 and providing the geometry encodings 418 to the emulator module 410.

The emulator training module 408 can be configured to train the emulator module 410. In some embodiments, the emulator training module 408 can train the emulator module 410 using automatic differentiation to train the machine learning parameters of the emulator training module 408 to minimize a loss function. An example of a loss function is a mean squared error loss function.

In example operation, the encoder module 404 can output the geometry encoding 418 for a first one of the images 318 (or multiple ones of the images 318 for batch training). The emulator module 410 can input the geometry encoding 418 and the motor states 420 into a machine learning model and output from the machine learning model predicted metrics 422.

By way of example, the emulator module 410 can execute a machine learning model using the geometry encoding 418 and the motor states 420 as input to emulate a performance of an electric motor design when in the motor states 420 as output. For example, the emulator module 410 can execute the machine learning model to emulate, using the encoding of the stationary components of the electric motor design, the electromechanical behavior of moveable components of the electric motor design.

In such an example, the emulator module 410 can provide the geometry encoding 418 and a motor state including a rotor angle value and/or a phase current value into a machine learning model and output from the machine learning model a torque value and a flux linkage value corresponding to the rotor angle value and/or the phase current value. For example, the emulator module 410 can emulate a performance of an electric motor design represented by the geometry encoding 418 when an angle of a rotor of the electric motor design is the rotor angle value and a current in at least one winding of the electric motor design is the phase current value.

The predicted metrics 422 can correspond to the simulated metrics 320 such that the emulator training module 408 can compare them to determine an error 424. For example, the predicted metrics 422 can be predicted electric motor metrics. The predicted metrics 422 may characterize the electromechanical behavior of the electric motor designs under the variety of operating conditions. For example, the predicted metrics 422 can be performance parameters, and each of which can contribute to generating and/or formulating a performance evaluation of the electric motor design under evaluation.

Examples of the predicted metrics include flux linkage, magnetic energy, magnetic co-energy, torque, and torque ripple. For example, the emulator module 410 can execute a machine learning model using the geometry encoding 418 as input to emulate a performance of an electric motor design as output, such as by outputting values of flux linkage, magnetic energy, magnetic co-energy, torque, and torque ripple when in the motor states 420.

By way of example, the variety of operating conditions can include values of rotor angles and phase currents. The emulator module 410 can be configured to input the rotor angle values and the phase current values into the machine learning model and output, from the machine learning model, values of at least one of a torque or a flux linkage for the respective rotor angle values and the phase current values. For example, the emulator module 410 can be configured to input a first rotor angle value and a first phase current value into the machine learning model and output, from the machine learning model, a first torque value and a first flux linkage value that corresponds to performance of the electric motor design having the first rotor angle value and the first phase current value.

By way of another example, the variety of operating conditions can include values of torque and flux linkage. The emulator module 410 can be configured to input the torque values and the flux linkage values into the machine learning model and output, from the machine learning model, values of at least one of a rotor angle or a phase current for the respective torque values and the flux linkage values. For example, the emulator module 410 can be configured to input a first torque value and a first flux linkage value into the machine learning model and output, from the machine learning model, a first rotor angle value and a first phase current value that corresponds to performance of the electric motor design having the first torque value and the first flux linkage value.

By way of yet another example, the variety of operating conditions can include values of temperature (e.g., motor temperature) and battery state. The emulator module 410 can be configured to input the temperature values and the battery state values into the machine learning model and output, from the machine learning model, values of at least one type of loss for the respective temperature values and the battery state values. For example, the emulator module 410 can be configured to input a first temperature value and a first battery state value into the machine learning model and output, from the machine learning model, a first alternating current loss value and/or a first core loss value that corresponds to performance of the electric motor design having the first temperature value and the first battery state value.

The emulator module 410 can output the error 424 to the emulator training module 408. Based on the error 424, the emulator module 410 can determine whether to retrain the emulator module 410 to reduce the error 424 (e.g., increase an accuracy of the emulator module 410) or deploy the emulator module 410 for inference operations.

In some embodiments, the emulator training module 408 can determine to retrain the emulator module 410 based on whether the error 424 meets and/or satisfies a threshold (e.g., an error threshold). For example, the emulator training module 408 can compare the error 424 to the threshold.

If the error 424 does not meet and/or satisfy the threshold, such as by being greater than the threshold, the emulator training module 408 can determine that the emulator module 410 has not achieved a sufficient level of accuracy and is to be retrained. For example, the emulator training module 408 can instruct the encoder module 404 to provide a geometry encoding 418 of a second one of the images 318 (or multiple geometry encodings 418 from another batch to be processed) to the emulator module 410 for retraining.

If the error 424 meets and/or satisfies the threshold, such as by falling below the threshold, the emulator training module 408 can determine that the emulator module 410 has achieved a sufficient level of accuracy and can be deployed for inference operations. For example, the emulator training module 408 can instruct the encoder module 404 to stop providing training data to the emulator module 410 such as by ceasing to provide geometry encodings 418 to the emulator module 410.

In some embodiments, the encoder module 404 and the emulator module 410 implement separable machine learning networks. For example, output(s) of the encoder module 404 may be connected to input(s) of the emulator module 410.

By way of example, the encoder module 404 can be a first machine learning model configured with a first number of machine learning parameters (e.g., a first number of machine learning weights and/or layers) and the emulator module 410 can be a second machine learning model configured with a second number of machine learning parameters (e.g., a second number of machine learning weights and/or layers). In such an example, the first number of machine learning parameters can be less than the second number of machine learning parameters. In some such embodiments, the encoder module 404 can be configured to execute a fewer number of times (e.g., once) than the emulator module 410 to generate the performance evaluation 512 for a particular electric motor design.

Beneficially, by configuring the larger and more computationally intensive encoder module 404 to execute a fewer number of times than the smaller and less computationally intensive emulator module 410, the performance evaluation 512 for a particular electric motor design can be generated with improved speed and reduced physical hardware resource consumption with respect to iteratively executing the larger and more computationally intensive machine learning model exclusively. For example, executing the encoder module 404 may take approximately 50 milliseconds and executing the emulator module 410 may take approximately 10 microseconds, which is several orders of magnitude less than the time to execute the encoder module 404.

While an example implementation of the electric motor design evaluation service 120 of FIG. 1 is depicted in FIG. 4, other implementations are contemplated. For example, one or more blocks, components, functions, etc., of the electric motor design evaluation service 120 may be combined or divided in any other way. The electric motor design evaluation service 120 of the illustrated example may be implemented by hardware alone, or by a combination of hardware, software, and/or firmware. For example, the electric motor design evaluation service 120 may be implemented by one or more analog or digital circuits (e.g., comparators, operational amplifiers, etc.), one or more hardware-implemented state machines, one or more programmable processors, one or more network interfaces, one or more ASICs, one or more memories, one or more mass storage disks or devices, etc., and/or any combination(s) thereof.

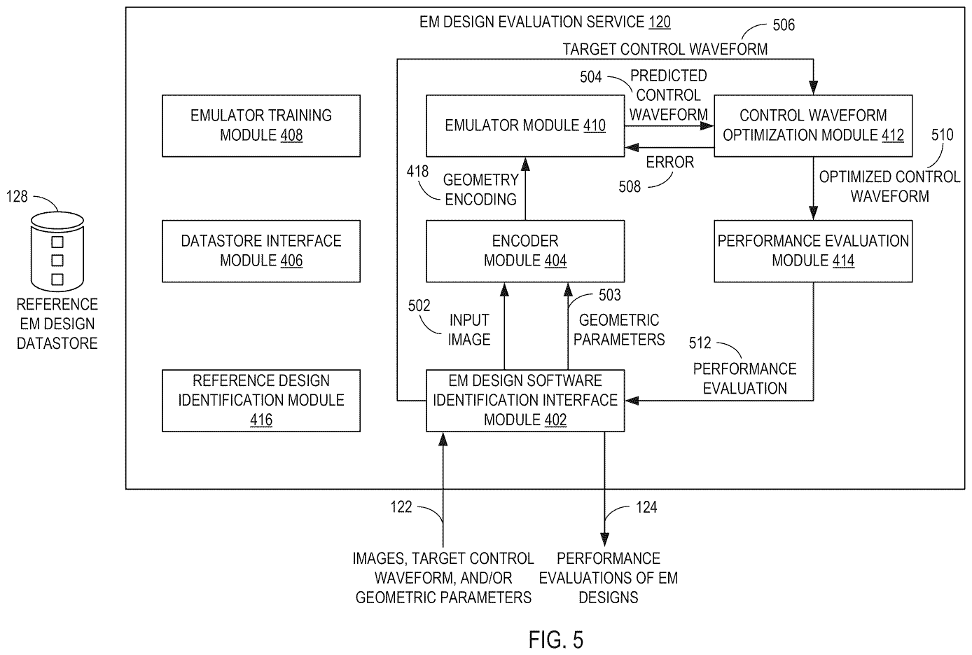

FIG. 5 depicts the block diagram of the electric motor design evaluation service 120 of FIG. 4 generating a performance evaluation of an input electric motor design. As shown, the electric motor design software identification interface module 402 receives the inputs 122 of FIG. 1. For example, the electric motor design software identification interface module 402 can receive one or more of the images 118, the target control waveform of the electric motor requirements 110 of FIG. 1, and/or one or more geometric parameters of the input electric motor design 112. The inputs 122 may include an image of the input electric motor design 112 and/or one or more images of variations of the input electric motor design 112.

In the illustrated example, the electric motor design software identification interface module 402 outputs an input image 502 to the encoder module 404. The input image 502 may be an image of the input electric motor design 112. Additionally and/or alternatively, the input image 502 may be the one or more images of variations of the input electric motor design 112. For example, the electric motor design software identification interface module 402 may output the image of the input electric motor design 112 and/or one or more images of variations of the input electric motor design 112 to effectuate batch processing of evaluating a plurality of electric motor designs.

Additionally and/or alternatively, the electric motor design software identification interface module 402 may output geometric parameters 503 to the encoder module 404. The geometric parameters 503 may be geometric parameters of the input electric motor design 112. Additionally and/or alternatively, the geometric parameters 503 may be variations of geometric parameters of the input electric motor design 112.

In some embodiments, the encoder module 404 can input the input image 502 to a machine learning model and output from the machine learning model the geometry encoding 418 of the input image 502. The emulator module 410 can input the geometry encoding 418 into a machine learning model and output from the machine learning model predicted metrics, such as the predicted metrics 422 of FIG. 4, which can be representative of a predicted control waveform 504. The predicted control waveform 504 may be used for control of an electric motor having the input electric motor design 112. For example, the predicted control waveform 504 may be a waveform shaped by at least one of a current magnitude, torque, or a voltage of the predicted metrics 422 and predicted by the emulator module 410. The emulator module 410 can output the predicted control waveform 504 to the control waveform optimization module 412.

In some embodiments, the encoder module 404 can input the geometric parameters 503 to a machine learning model and output from the machine learning model the geometry encoding 418 of the geometric parameters 503. The emulator module 410 can input the geometry encoding 418 into a machine learning model and output from the machine learning model predicted metrics, such as the predicted metrics 422 of FIG. 4, which can be representative of the predicted control waveform 504. The predicted control waveform 504 may be used for control of an electric motor having the geometric parameters 503.

In the shown example, the control waveform optimization module 412 can be configured to optimize and/or otherwise improve the predicted control waveform 504. For example, the control waveform optimization module 412 can compare (i) a target control waveform 506 from the inputs 122 and output from the electric motor design software identification interface module 402 and (ii) the predicted control waveform 504. In such an example, the control waveform optimization module 412 can determine an error 508 based on the comparison.

In some embodiments, the control waveform optimization module 412 can be and/or be implemented by a gradient-based optimizer to find an optimized control waveform 510 given control constraints, such as constraints on current magnitude, torque, and/or voltage. The gradient-based optimizer may be a Sequential Least Squares Programming (SLSQP) optimizer.

As shown, the control waveform optimization module 412 can output the error 508 to the emulator module 410 which, in turn, can generate another predicted control waveform 504 based on the error 508. The emulator module 410 and the control waveform optimization module 412 can iteratively execute their respective processes until the error 508 meets and/or satisfies a threshold (e.g., an error threshold).

By way of example, if the error 508 does not meet and/or satisfy the threshold, such as by being greater than the threshold, the control waveform optimization module 412 can determine that the emulator module 410 has not output the predicted control waveform 504 that minimizes and/or otherwise reduces the error 508. For example, the control waveform optimization module 412 can output the error 508 to cause the emulator module 410 to re-execute to generate another predicted control waveform 504 to reduce the error 508.

If the error 508 meets and/or satisfies the threshold, such as by falling below the threshold, the control waveform optimization module 412 can determine that the predicted control waveform 504 minimizes and/or otherwise reduces the error 508. For example, the control waveform optimization module 412 can output the predicted control waveform 504 that minimizes the error 508 as the optimized control waveform 510.

As depicted, the control waveform optimization module 412 can output the optimized control waveform 510 to the performance evaluation module 414. The performance evaluation module 414 can be configured to emulate performance of an electric motor design corresponding to the input image 502 (and/or the geometric parameters 503) by emulating operation of the electric motor design in accordance with the optimized control waveform 510. For example, the performance evaluation module 414 can predict metrics, such as the predicted metrics 422, of the electric motor design when controlled and/or operated under a variety of operating conditions and using the optimized control waveform 510.

In some embodiments, the control waveform optimization module 412 can output the optimized control waveform 510 to the emulator module 410. The emulator module 410 can be configured to emulate performance of an electric motor design corresponding to the input image 502 (and/or the geometric parameters 503) by emulating operation of the electric motor design in accordance with the optimized control waveform 510. For example, the emulator module 410 can predict metrics, such as the predicted metrics 422, of the electric motor design when controlled and/or operated under a variety of operating conditions and using the optimized control waveform 510. In some such embodiments, the emulator module 410 can output the predicted metrics 422 to the performance evaluation module 414 to generate a performance evaluation 512.

In the illustrated example, the performance evaluation module 414 can output the performance evaluation 512 using the predicted metrics. For example, the emulator module 410 and/or the performance evaluation module 414 can predict flux linkage, magnetic energy, magnetic co-energy, torque, and/or torque ripple of an electric motor design for a plurality of the motor states 420 and when controlled using the optimized control waveform 510. In such an example, the performance evaluation module 414 can output the predicted flux linkage, magnetic energy, magnetic co-energy, torque, and/or torque ripple of the electric motor design corresponding to a processed input image, such as the input image 502, as the performance evaluation 512.

As illustrated, the performance evaluation module 414 can output the performance evaluation 512 to the electric motor design software identification interface module 402. The electric motor design software identification interface module 402 may output the performance evaluation 512 to the electric motor design identification software 102 as one of the performance evaluations 124.

In some embodiments, one or more components of the electric motor design evaluation service 120 of the illustrated example can generate the performance evaluation 512 for respective ones of a plurality of electric motor designs substantially in parallel. For example, respective instances of the encoder module 404, the emulator module 410, the control waveform optimization module 412, and/or the performance evaluation module 414 may be executed for each electric motor design to be processed. In such an example, first instances of the encoder module 404, the emulator module 410, the control waveform optimization module 412, and/or the performance evaluation module 414 may be executed to generate a first performance evaluation for a first electric motor design corresponding to a first input image, second instances of the encoder module 404, the emulator module 410, the control waveform optimization module 412, and/or the performance evaluation module 414 may be executed to generate a second performance evaluation for a second electric motor design corresponding to a second input image, and so on. In some such examples, the plurality of instances of the encoder module 404, the emulator module 410, the control waveform optimization module 412, and/or the performance evaluation module 414 may be executed substantially in parallel to generate the performance evaluation 512 for each of the electric motor designs being evaluated. In some embodiments, hundreds, thousands, or tens of thousands of compute resources (e.g., CPUs, CPU cores, GPUs, GPU cores) can execute the respective instances substantially in parallel.

In some embodiments, the electric motor design evaluation service 120 of the illustrated example can generate the performance evaluation 512 for respective ones of a plurality of electric motor designs substantially in parallel. For example, an instance of the electric motor design evaluation service 120 may be executed for each electric motor design to be processed. In such an example, a first instance of the electric motor design identification software 102 may be executed to generate a first performance evaluation for a first electric motor design corresponding to a first input image, a second instance of the electric motor design identification software 102 may be executed to generate a second performance evaluation for a second electric motor design corresponding to a second input image, and so on. In some such examples, the plurality of instances of the electric motor design evaluation service 120 may be executed substantially in parallel to generate the performance evaluation 512 for each of the electric motor designs being evaluated. In some embodiments, hundreds, thousands, or tens of thousands of compute resources (e.g., CPUs, CPU cores, GPUs, GPU cores) can execute the respective instances substantially in parallel.

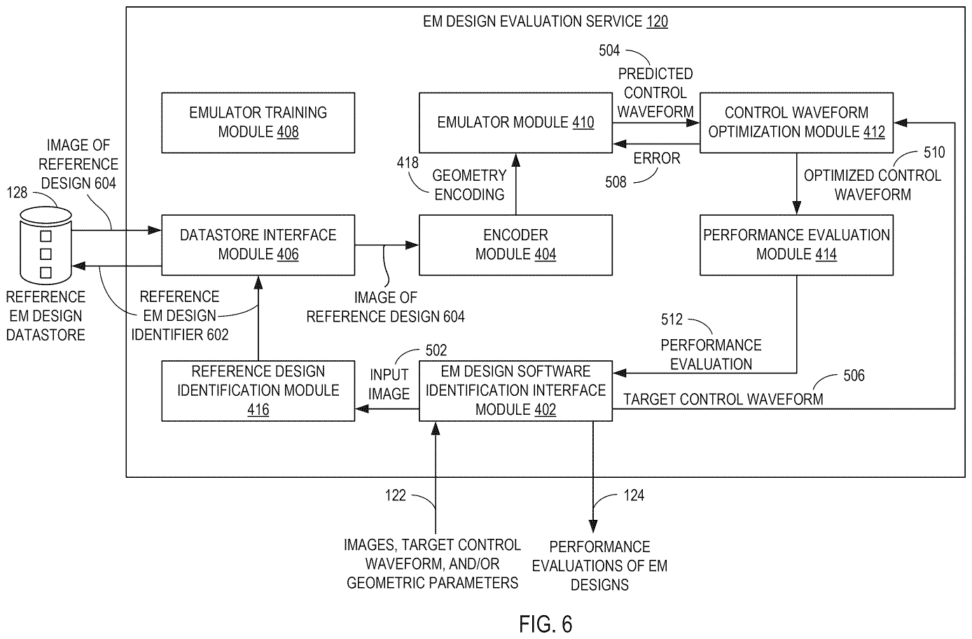

FIG. 6 depicts the block diagram of the electric motor design evaluation service 120 of FIGS. 4 and/or 5 generating performance evaluations for reference electric motor designs. As shown, the electric motor design software identification interface module 402 receives the inputs 122 of FIG. 1. For example, the electric motor design software identification interface module 402 can receive one or more of the images 118, the target control waveform of the electric motor requirements 110 of FIG. 1, and/or the geometric parameters of the input electric motor design 112.

The inputs 122 may include an image of the input electric motor design 112 and/or one or more images of variations of the input electric motor design 112. The inputs 122 may include geometric parameters of the input electric motor design 112 and/or geometric parameters that are variations of the geometric parameters of the input electric motor design 112.

In the illustrated example, the electric motor design software identification interface module 402 outputs the input image 502 of FIG. 5 to the reference design identification module 416. Additionally and/or alternatively, the electric motor design software identification interface module 402 may output the geometric parameters to the reference design identification module 416.

The input image 502 may be an image of the input electric motor design 112. For example, the electric motor design software identification interface module 402 may output the image of the input electric motor design 112 to the reference design identification module 416 to identify one(s) of the reference electric motor designs 126 associated with the input electric motor design 112. Additionally and/or alternatively, the input image 502 may be the one or more images of variations of the input electric motor design 112. For example, the electric motor design software identification interface module 402 may output the image of a variation of the input electric motor design 112 to the reference design identification module 416 to identify one(s) of the reference electric motor designs 126 associated with the variation of the input electric motor design 112.

In some embodiments, the reference design identification module 416 can be configured to search the reference electric motor design datastore 128 for one(s) of the reference electric motor designs 126 that is/are associated with the input image 502. For example, the reference design identification module 416 can be configured to identify similar electric motor designs to the electric motor design represented by the input image 502. In such an example, the similar electric motor designs may have one or more geometric parameters that are the same and/or similar to the electric motor design represented by the input image 502.

In some embodiments, the reference design identification module 416 can be configured to search the reference electric motor design datastore 128 for one(s) of the reference electric motor designs 126 that is/are associated with the geometric parameters. For example, the reference design identification module 416 can be configured to map the geometric parameters to a plurality of electric motor designs. In such an example, the reference design identification module 416 can be configured to perform the mapping by identifying similar electric motor designs to the electric motor design represented by the geometric parameters. In such an example, the similar electric motor designs may have one or more geometric parameters that are the same and/or similar to the electric motor design represented by the geometric parameters.

In some embodiments, the reference design identification module 416 can be and/or be implemented by a gradient-free optimizer. An example of a gradient-free optimizer is the Non-dominated Sorting Genetic Algorithm II (NSGA-II). For example, the reference design identification module 416 can execute, perform, and/or carry out the NSGA-II using the input image 502 as input to identify one(s) of the reference electric motor designs 126 as output.

Additionally and/or alternatively, the reference design identification module 416 can be configured to identify one(s) of the reference electric motor designs 126 that optimize one or more metrics. For example, the reference design identification module 416 can be configured to search the reference electric motor design datastore 128 for one(s) of the reference electric motor designs 126 that optimize one or more metrics, such as flux linkage, magnetic energy, magnetic co-energy, torque, and torque ripple. In such an example, the reference design identification module 416 can execute the NSGA-II to identify which one(s) of the reference electric motor designs 126 optimize torque, such as which one(s) of the reference electric motor designs 126 maximize torque given one or more other constraints.

In example operation, the reference design identification module 416 can identify one or more of the reference electric motor designs 126. The reference design identification module 416 can determine that each of the identified reference electric motor designs 126 has an associated identifier 602. Examples of the identifier include a numeric identifier and an alphanumeric identifier.

The reference design identification module 416 can provide the reference electric motor design identifier 602 to the datastore interface module 406 which, in turn, can retrieve an image 604 that corresponds to the associated identifier 602 from the reference electric motor design datastore 128. The datastore interface module 406 can output the retrieved image 604 of the reference electric motor design to the encoder module 404.

In example operation, the encoder module 404 can convert the image 604 into the geometry encoding 418. The encoder module 404 can output the geometry encoding 418 to the emulator module 410. The emulator module 410 can provide the geometry encoding 418 to a machine learning model and output from the machine learning model the predicted control waveform 504. The emulator module 410 can output the predicted control waveform 504 to the control waveform optimization module 412.

In example operation, the control waveform optimization module 412 can determine the error 508 based on a comparison (e.g., a difference) of the predicted control waveform 504 and the target control waveform 506. After the control waveform optimization module 412 determines that the error 508 is minimized, such as by meeting and/or satisfying a threshold as described herein, the control waveform optimization module 412 outputs the predicted control waveform 504 as the optimized control waveform 510 to the performance evaluation module 414. Additionally and/or alternatively, the control waveform optimization module 412 may output the optimized control waveform 510 to the emulator module 410.

In example operation, the performance evaluation module 414 can generate the performance evaluation 512 by emulating a performance of the electric motor design represented by the geometry encoding 418 of the input image 502 using the optimized control waveform 510 under a variety of operating conditions. The performance evaluation module 414 can output the emulated performance as the performance evaluation 512. The electric motor design software identification interface module 402 can output the performance evaluation 512 as at least one of the performance evaluations 124 to the electric motor design identification software 102.

In another example operation, the emulator module 410 can generate the performance evaluation 512 by emulating a performance of the electric motor design represented by the geometry encoding 418 of the input image 502 using the optimized control waveform 510 under a variety of operating conditions. The emulator module 410 can output the emulated performance to the performance evaluation module 414, which can output the emulated performance as the performance evaluation 512. The electric motor design software identification interface module 402 can output the performance evaluation 512 as at least one of the performance evaluations 124 to the electric motor design identification software 102.

In some embodiments, the electric motor design evaluation service 120 of the illustrated example can generate the performance evaluation 512 for respective ones of a plurality of reference electric motor designs substantially in parallel. For example, an instance of the electric motor design evaluation service 120 may be executed for each reference electric motor design to be processed. In such an example, a first instance of the electric motor design identification software 102 may be executed to generate a first performance evaluation for a first reference electric motor design corresponding to a first image of a first reference electric motor design from the reference electric motor design datastore 128, a second instance of the electric motor design identification software 102 may be executed to generate a second performance evaluation for a second reference electric motor design corresponding to a second image of a second reference electric motor design from the reference electric motor design datastore 128, and so on. In some such examples, the plurality of instances of the electric motor design evaluation service 120 may be executed substantially in parallel to generate the performance evaluation 512 for each of the identified reference electric motor designs being evaluated.

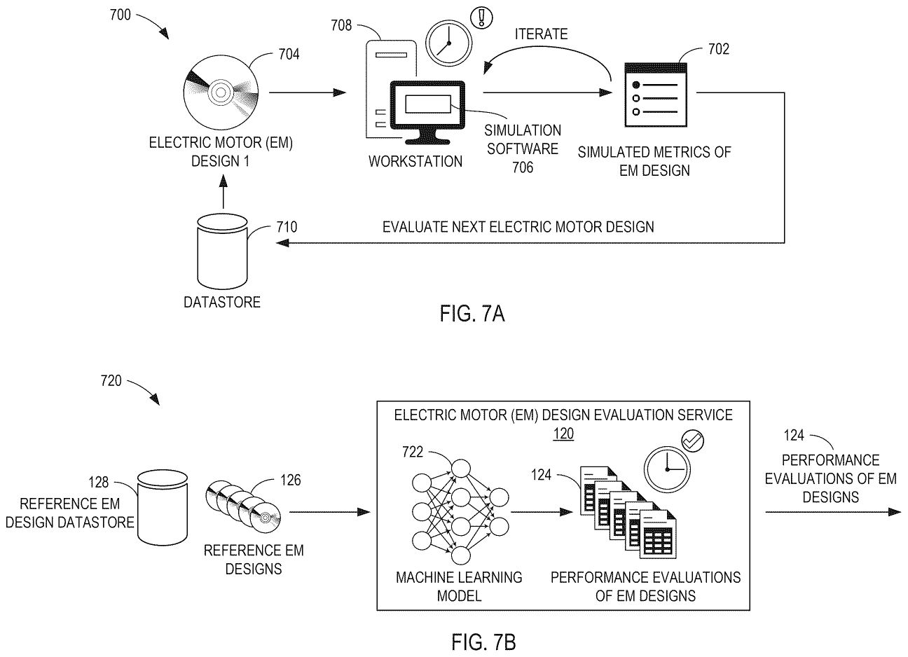

FIG. 7A depicts an example workflow 700 of generating simulated metrics 702 of an electric motor design 704 using electric motor simulation software 706. For example, the electric motor simulation software 706 may be simulation software that uses finite element analysis (FEA) to simulate electric motor metrics of the electric motor design 704. For example, the electric motor simulation software 706 may use a CAD model of a geometry of the electric motor design 704 to apply 3-phase currents to the stator windings in the CAD model over a range of frequencies to output the simulated metrics 702 as the simulation results. The simulated metrics may include an evaluation of the flux linkage of one phase for each simulation run.

In the illustrated example, the simulation may be iterated for each phase. However, as shown, using the electric motor simulation software 706 to evaluate a single electric motor design 704 can consume a substantial amount of hardware computational resources, such as processing power, memory, mass storage, and network bandwidth of a workstation 708, such as a desktop computer. After the electric motor design 704 is evaluated, the workflow 700 may repeat to evaluate another electric motor design retrieved from a datastore 710. As shown, the workflow 700 is repeated sequentially to evaluate electric motor designs, which further leads to computational inefficiencies by evaluating electric motor designs in sequence rather than in parallel.

FIG. 7B depicts an example workflow 720 of characterizing a plurality of electric motor designs using at least the electric motor design evaluation service 120 of FIG. 1. As depicted, the workflow 720 includes evaluating a plurality of electric motor designs, which are shown as a plurality of the reference electric motor designs 126 from the reference electric motor design datastore 128 of FIG. 1.

The implementation of the electric motor design evaluation service 120 shown includes a machine learning model 722 and a plurality of performance evaluations 724. The machine learning model 722 can be implemented by the emulator module 410 of FIGS. 4-6. The plurality of plurality of performance evaluations 724 can be implemented by ones of the performance evaluation 512 of FIGS. 5-6.

In example operation, the machine learning model 722 can be executed using the reference electric motor designs 126 as input to generate the respective performance evaluations 124 as output. As shown, the workflow 720 can process the reference electric motor designs 126 substantially in parallel to generate the performance evaluations 124 in substantially less time with respect to generating the performance evaluations 124 with simulation software, such as the electric motor simulation software 706 of FIG. 7A.

Beneficially, using the machine learning model 722 to evaluate a plurality of the performance evaluations 124 can consume substantially fewer hardware computational resources, such as processing power, memory, mass storage, and network bandwidth, to generate the performance evaluations 124 with respect to the quantity of hardware computational resources consumed by the workstation 708 of FIG. 7A to generate the simulated metrics 702 for a single electric motor design.

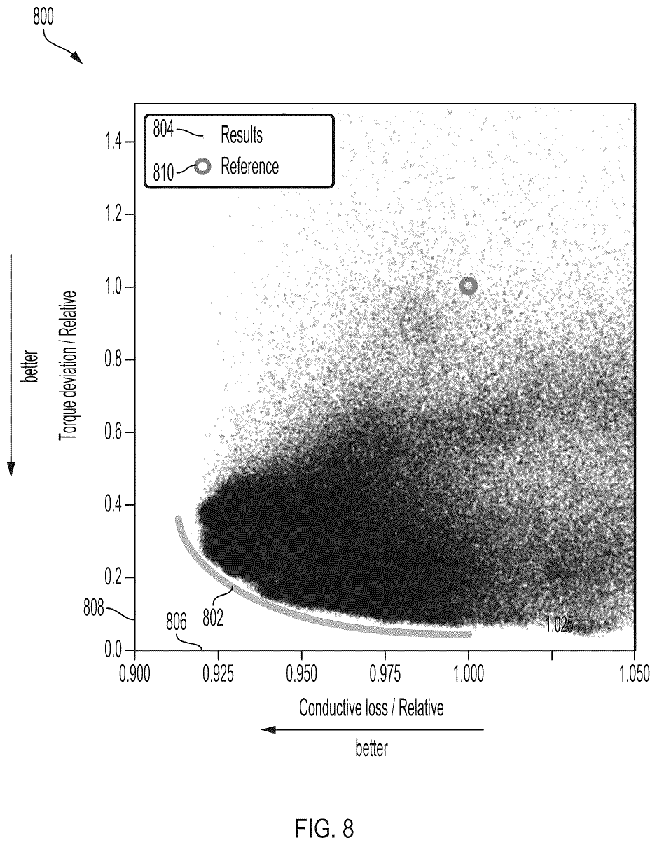

FIG. 8 depicts a plot 800, which includes a Pareto front 802 that is generated using performance evaluations 804 for a plurality of electric motor designs. For example, the performance evaluations can correspond to the performance evaluations 124 of FIG. 1 and/or the performance evaluation 512 of FIGS. 5 and/or 6.

As shown, each of the performance evaluations 804 is plotted with respect to an x-axis 806 and a y-axis 808. The x-axis 806 represents relative conductive loss for an electric motor design and the y-axis 808 represents relative torque deviation for an electric motor design. For example, the conductive loss and the torque deviation metrics of the performance evaluations 804 can be set and/or scaled according to a conductive loss and torque deviation metric of a reference electric motor design 810. For example, the reference electric motor design 810 can be set to have a conductive loss of 1.000 and a torque deviation of 1.000 and each of the performance evaluations 804 can be set relative to these values, such as having values greater than, equal to, and/or less than these values.

In the illustrated example, improved and/or otherwise optimized ones of the performance evaluations 804 have lower relative torque deviation and lower relative conductive loss. These improved and/or otherwise optimized performance evaluations 804 are represented by the Pareto front 802.

In some embodiments, the electric motor design identification software 102 of FIG. 1 generates and/or outputs the Pareto front 802. For example, the electric motor evaluation service interface module 208 of FIG. 2 can receive the performance evaluations 804 from the electric motor design evaluation service 120. In such an example, the electric motor design requirements optimization module 212 can generate the Pareto front 802 using the performance evaluations 804.

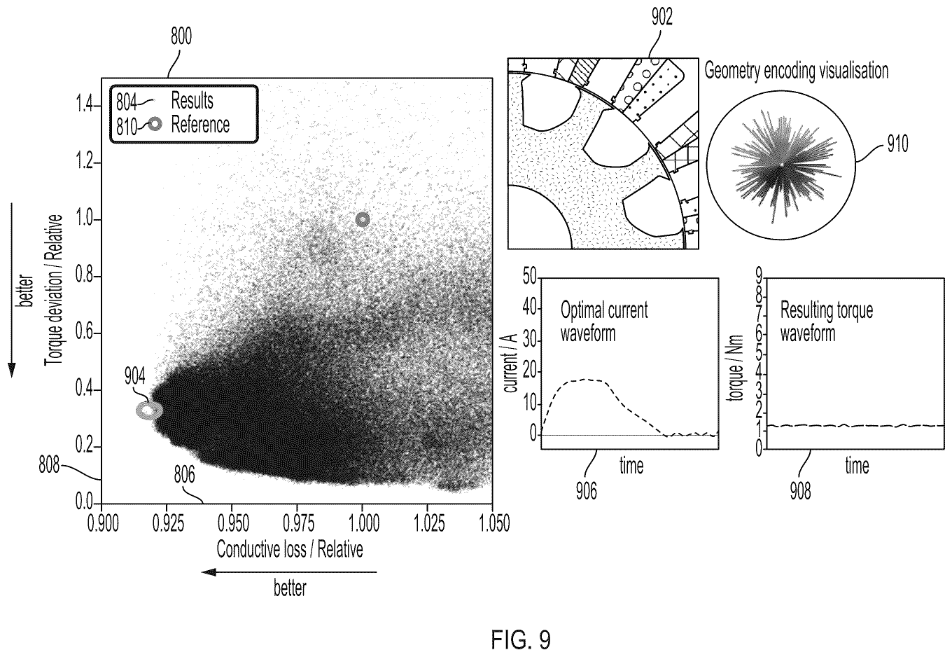

FIG. 9 depicts a selection of an example electric motor design 902 from the Pareto front 802 of FIG. 8. For example, the electric motor design identification module 210 and/or the electric motor design requirements optimization module 212 of FIG. 2 can select a performance evaluation 904, which corresponds to the electric motor design 902, from the Pareto front 802 of FIG. 8 and/or, more generally, the plot 800 of FIG. 8. As shown, the performance evaluation 904 can correspond to the electric motor design 902, which has optimized and/or otherwise reduced values for torque deviation and conductive loss relative to the other performance evaluations 804.

Also shown in the example of FIG. 9 is a plot 906 of the optimal current waveform and a plot 908 of the resulting torque waveform of the electric motor design 902. As shown, the plot 906 includes values of a current metric (e.g., a current waveform) with respect to time and the plot 908 includes values of a torque metric (e.g., a torque waveform) with respect to time. For example, the plots 906, 908 can represent values of metrics included in the performance evaluation 904 for the electric motor design 902.

Further shown in the example of FIG. 9 is a geometry encoding visualization 910. The radius of each line in the geometry encoding visualization 910 is the function of one element of the encoding vector.

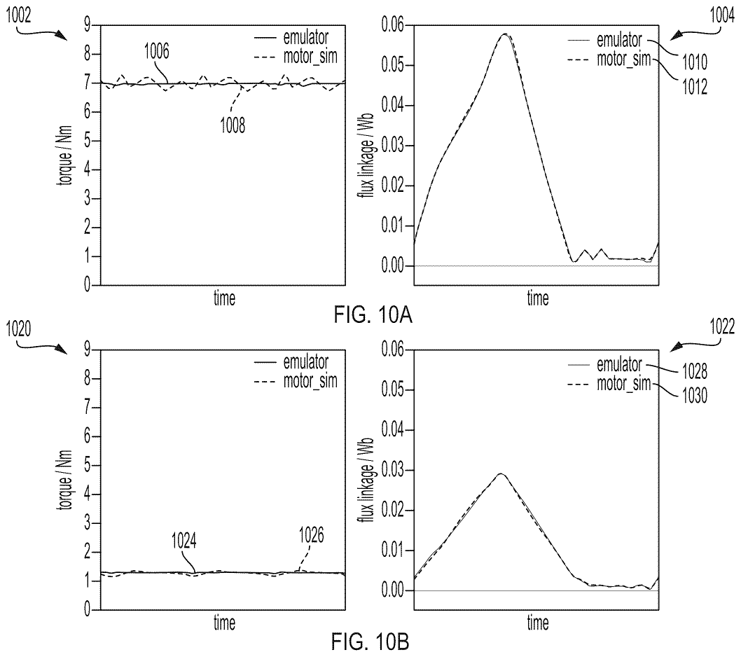

FIG. 10A depicts a first plot 1002 and a second plot 1004 of example predicted and simulated metrics 1006, 1008, 1010, 1012 for a first electric motor design, such as the input electric motor design 112 of FIG. 1 and/or the electric motor design 902 of FIG. 9. The first plot 1002 shows first values of a predicted metric 1006 and first values of a simulated metric 1008 for the first electric motor design.

The predicted metric 1006 is torque measured in Newton-meters (Nm) with respect to time. For example, the first values of the predicted metric 1006 can be values output from a machine learning model. In such an example, the first values of the predicted metric 1006 can be values of one of the predicted metrics 422 of FIG. 4.

The simulated metric 1008 is torque measured in Nm with respect to time. For example, the first values of the simulated metric 1008 can be values output from a simulation module, such as the simulation module 310 of FIG. 3. In such an example, the first values of the simulated metric 1008 can be values of one of the simulated metrics 320 of FIG. 3.

As shown in the first plot 1002, values of the predicted metric 1006 and the simulated metric 1008 are substantially similar, which indicates that accuracy of the machine learning model of the emulator module 410 is commensurate with the accuracy of the simulation module 310. Beneficially, obtaining outputs from the emulator module 410 is substantially faster than obtaining outputs from the simulation module 310 and without a significant deviation in accuracy. Accordingly, obtaining outputs with greater speed and similar accuracy via the emulator module 410 can achieve improvements in hardware computational efficiency, which enables the electric motor design evaluation service 120 to generate the performance evaluation 512 substantially in parallel.

Also shown in FIG. 10A, is the second plot 1004, which shows second values of a predicted metric 1010 and second values of a simulated metric 1012 for the first electric motor design.

The predicted metric 1010 is flux linkage measured in webers (Wb) with respect to time. For example, the second values of the predicted metric 1010 can be values output from a machine learning model. In such an example, the second values of the predicted metric 1010 can be values of one of the predicted metrics 422 of FIG. 4.

The simulated metric 1012 is flux linkage measured in Wb with respect to time. For example, the second values of the simulated metric 1012 can be values output from a simulation module, such as the simulation module 310 of FIG. 3. In such an example, the second values of the simulated metric 1012 can be values of one of the simulated metrics 320 of FIG. 3.

Like the first plot 1002, the second plot 1004 shows that values of the predicted metric 1010 and the simulated metric 1012 are substantially similar, which indicates that accuracy of the machine learning model of the emulator module 410 is commensurate with the accuracy of the simulation module 310.

FIG. 10B depicts a third plot 1020 and a fourth plot 1022 of example predicted and simulated metric 1024, 1026, 1028, 1030 for a second electric motor design, such as one of the reference electric motor designs 126 of FIG. 1. Alternatively, the second electric motor design may be the input electric motor design 112 of FIG. 1 and/or the electric motor design 902 of FIG. 9.

The third plot 1020 shows third values of a predicted metric 1024 and third values of a simulated metric 1026 for the second electric motor design. The predicted metric 1024 is torque measured in Nm with respect to time. For example, the third values of the predicted metric 1024 can be values output from a machine learning model. In such an example, the third values of the predicted metric 1024 can be values of one of the predicted metrics 422 of FIG. 4.

The simulated metric 1026 is torque measured in Nm with respect to time. For example, the third values of the simulated metric 1026 can be values output from a simulation module, such as the simulation module 310 of FIG. 3. In such an example, the third values of the simulated metric 1026 can be values of one of the simulated metrics 320 of FIG. 3.

As shown in the third plot 1020, values of the predicted metric 1006 and the simulated metric 1008 are substantially similar, which indicates that accuracy of the machine learning model of the emulator module 410 is commensurate with the accuracy of the simulation module 310.

Also shown in FIG. 10B, is the fourth plot 1022, which shows fourth values of a predicted metric 1028 and fourth values of a simulated metric 1030 for the second electric motor design.

The predicted metric 1028 is flux linkage measured in Wb with respect to time. For example, the fourth values of the predicted metric 1028 can be values output from a machine learning model. In such an example, the fourth values of the predicted metric 1028 can be values of one of the predicted metrics 422 of FIG. 4.

The simulated metric 1030 is flux linkage measured in Wb with respect to time. For example, the fourth values of the simulated metric 1030 can be values output from a simulation module, such as the simulation module 310 of FIG. 3. In such an example, the fourth values of the simulated metric 1030 can be values of one of the simulated metrics 320 of FIG. 3.

Like the first plot 1002, the second plot 1004, and the third plot 1020, the fourth plot 1022 shows that values of the predicted metric 1028 and the simulated metric 1030 are substantially similar, which indicates that accuracy of the machine learning model of the emulator module 410 is commensurate with the accuracy of the simulation module 310.

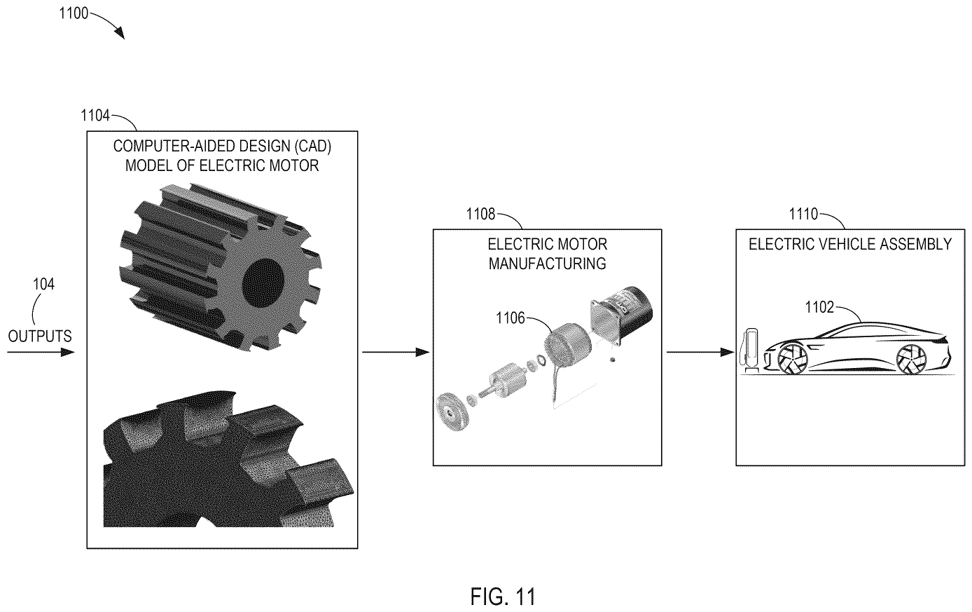

FIG. 11 depicts an example workflow 1100 to assemble and/or manufacture an electric vehicle 1102 using an identified electric motor design. The workflow 1100 begins with receiving the outputs 104 from the electric motor design identification software 102 of FIG. 1. The outputs 104 include an electric motor design, which may include a CAD model 1104 of an electric motor.

During the workflow 1100, a physical electric motor 1106 is manufactured during an electric motor manufacturing operation 1108. For example, one or more physical components can be constructed using the CAD model 1104. Examples of the physical components include at least one of a flange bracket, a motor case, a stator, a bearing, a rotor, or a shaft.

Continuing the workflow 1100, the physical electric motor 1106 can be incorporated and/or integrated into an electric vehicle sub-assembly and/or, more generally, into the electric vehicle 1102, during electric vehicle assembly 1110. For example, the physical electric motor 1106 can be incorporated into an electric vehicle sub-assembly, such as an electric motor compartment of the electric vehicle 1102. In such an example, the electric motor component can be incorporated into the electric vehicle 1102.

In some embodiments, the physical electric motor 1106 can be controlled using the optimized control waveform 510 of FIG. 5 generated by the control waveform optimization module 412 of FIGS. 4-6. For example, in response to driver commands (e.g., pressing an acceleration pedal, pressing a brake pedal, etc., of the electric vehicle 1102), a motor controller of the electric vehicle 1102 can be configured and/or programmed to control the physical electric motor 1106 in accordance with the optimized control waveform 510.

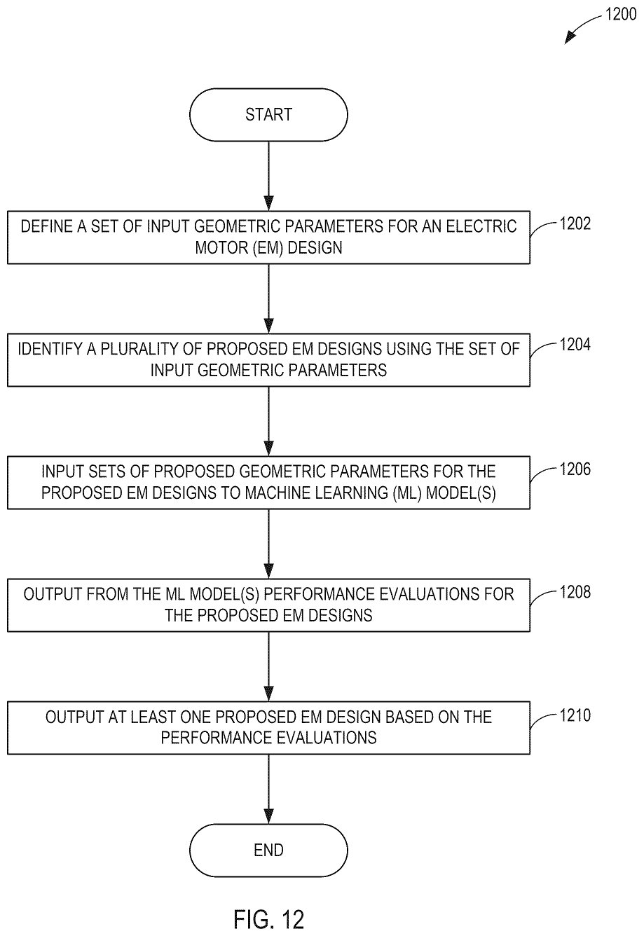

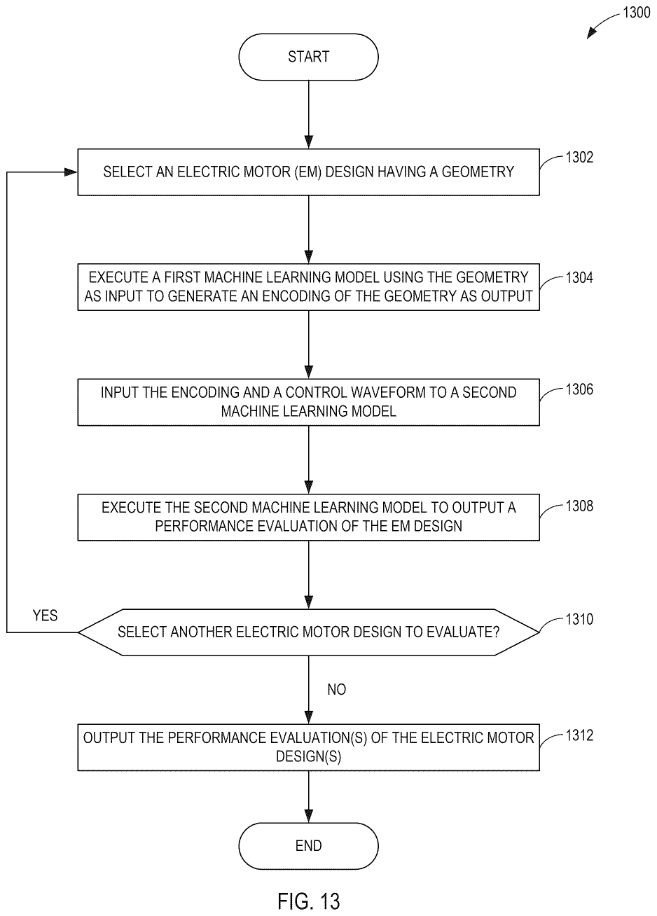

FIGS. 12 and 13 are flowcharts representative of example processes to be performed and/or example machine-readable instructions that may be executed by processor circuitry to implement the electric motor design identification software 102, the electric motor design image processing service 114, and/or the electric motor design evaluation service 120 of FIGS. 1, 2, 3, 4, 5, and/or 6. Although a flowchart may be discussed in connection with one of the electric motor design identification software 102, the electric motor design image processing service 114, and/or the electric motor design evaluation service 120 of FIGS. 1, 2, 3, 4, 5, and/or 6, the flowcharts may also be applicable to any other one(s) of the electric motor design identification software 102, the electric motor design image processing service 114, and/or the electric motor design evaluation service 120 of FIGS. 1, 2, 3, 4, 5, and/or 6. Additionally or alternatively, block(s) of one(s) of the flowcharts of FIGS. 12 and/or 13 may be representative of state(s) of one or more hardware-implemented state machines, algorithm(s) that may be implemented by hardware alone such as an ASIC, etc., and/or any combination(s) thereof.

FIG. 12 is a flowchart 1200 representative of an example process that may be performed and/or example machine-readable instructions that may be executed by processor circuitry to implement the electric motor design identification software 102, the electric motor design image processing service 114, and/or the electric motor design evaluation service 120 of FIGS. 1, 2, 3, 4, 5, and/or 6.

The flowchart 1200 of FIG. 12 begins at block 1202, at which the electric motor design identification software 102 may define a set of input geometric parameters for an electric motor design. For example, the input interface module 202 can receive the inputs 106, which can include the electric motor requirements 110, the input electric motor design 112, and/or geometric parameters of the input electric motor design 112. The orchestration module 204 may determine that the set of input geometric parameters include a length, width, height, depth, weight, and/or thickness of one or more electric motor components, such as the bearings, stator, and/or rotor of an electric motor. In some embodiments, based on the determination, the orchestration module 204 can route portion(s) of the inputs 106 to different modules, such as routing the input electric motor design 112 to the electric motor design image processing service 114 and/or routing the electric motor requirements 110 to the electric motor design requirements optimization module 212.

At block 1204, the electric motor design image processing service 114 and/or the electric motor design evaluation service 120 may identify a plurality of proposed electric motor designs using the set of input geometric parameters. For example, the electric motor design image processing service 114 and/or the electric motor design evaluation service 120 may map one(s) of the geometric parameters to a plurality of electric motor designs. In such an example, the plurality of proposed electric motor designs can be candidate electric motor designs from which at least one may be selected for output as the electric motor design 108 and/or, more generally, the outputs 104 of FIG. 1.

In some embodiments, the electric motor design image processing service 114 can identify a plurality of proposed electric motor designs by creating new electric motor designs by varying geometric parameter(s) of the input electric motor design 112. For example, the parameter variation module 306 can generate the geometric parameter variations 316, which can be used to create the images 318 that represent new electric motor designs.

Additionally and/or alternatively, in some embodiments, the electric motor design evaluation service 120 identifies a plurality of proposed electric motor designs by identifying one(s) of the reference electric motor designs 126 in the reference electric motor design datastore 128 that is/are associated with the input image 502 and/or the geometric parameters 503. For example, the reference design identification module 416 may map one(s) of the geometric parameters 503, such as one(s) of the geometric parameters of the input electric motor design 112, to a plurality of electric motor designs stored in and/or otherwise accessible via the reference electric motor design datastore 128. In such an example, the reference design identification module 416 can determine one(s) of the reference electric motor designs 126 that have the same and/or similar geometric parameter(s) of the input image 502 and/or the geometric parameters 503 such that similar electric motor designs can be evaluated.

At block 1206, the electric motor design evaluation service 120 may input sets of proposed geometric parameters for the proposed electric motor designs to machine learning model(s). For example, the electric motor design evaluation service 120 may input respective sets of proposed geometric parameters into the encoder module 404. In such an example, the electric motor design evaluation service 120 may input the respective sets of proposed geometric parameters into the encoder module 404 substantially in parallel. In some such embodiments, the encoder module 404 can process the respective sets of proposed geometric parameters as input to generate respective geometry encodings 418 as output. For example, the encoder module 404 can generate a geometry encoding 418 for each set of proposed geometric parameters, and each set of proposed geometric parameters corresponds to an electric motor design.

At block 1208, the electric motor design evaluation service 120 may output from the machine learning model(s) performance evaluations for the proposed electric motor designs. For example, the emulator module 410 and/or the performance evaluation module 414 may output a respective performance for the respective geometry encodings 418.

In some embodiments, the emulator module 410 can output a respective predicted control waveform 504 for the proposed electric motor designs. In such an example, the control waveform optimization module 412 can output, using the predicted control waveforms 504, a respective optimized control waveform 510 for the proposed electric motor designs. The performance evaluation module 414 can generate a respective performance evaluation 512 for the proposed electric motor designs.

At block 1210, the electric motor design identification software 102 may output at least one proposed electric motor design based on the performance evaluations. For example, the electric motor design requirements optimization module 212 can generate the Pareto front 802 of FIG. 8 using the respective performance evaluations 512 for the proposed electric motor designs. In such an example, the electric motor design identification module 210 and/or the electric motor design requirements optimization module 212 can select the performance evaluation 904 of FIG. 9 as the electric motor design 108 of FIG. 1. After outputting the at least one proposed electric motor design at block 1210, the example flowchart 1200 of FIG. 12 concludes.

FIG. 13 is a flowchart 1300 representative of an example process that may be performed and/or example machine-readable instructions that may be executed by processor circuitry to implement the electric motor design evaluation service 120 of FIGS. 1, 4, 5, and/or 6 to output performance evaluation(s). The flowchart 1300 of FIG. 13 begins at block 1302, at which the electric motor design evaluation service 120 may select an electric motor design having a geometry. For example, the electric motor design software identification interface module 402 can select a first input image 502 corresponding to a first electric motor design. The first electric motor design can have a first geometry, such as having one or more components (e.g., a bearing, a rotor, a stator) having respective geometric parameter(s) (e.g., a length of a bearing, a width of the bearing, etc.). In another example, the electric motor design software identification interface module 402 can select a first set of geometric parameters.

At block 1304, the electric motor design evaluation service 120 may execute a first machine learning model using the geometry as input to generate an encoding of the geometry as output. For example, the encoder module 404 can input the input image 502 into a first machine learning model and output from the first machine learning model the geometry encoding 418 of the input image 502. In another example, the encoder module 404 can input the first set of geometric parameters into a first machine learning model and output from the first machine learning model the geometry encoding 418 of the first set of geometric parameters.

At block 1306, the electric motor design evaluation service 120 may input the encoding and a control waveform to a second machine learning model. For example, the emulator module 410 can input the geometry encoding 418 and a control waveform into a second machine learning model. The control waveform may be the target control waveform 214 of FIG. 2 and/or the optimized control waveform 510 of FIGS. 5 and/or 6.

At block 1308, the electric motor design evaluation service 120 may execute the second machine learning model to output a performance evaluation of the electric motor design. For example, the emulator module 410 can output, from the second machine learning model, predicted metrics for the first electric motor design by emulating performance of the first electric motor design being controlled in accordance with the control waveform. In another example, the performance evaluation module 414 can output, from the second machine learning model, predicted metrics for the first electric motor design by emulating performance of the first electric motor design being controlled in accordance with the control waveform. The predicted metrics may be used to generate the performance evaluation 512.

At block 1310, the electric motor design evaluation service 120 may determine whether to select another electric motor design to evaluate. For example, the electric motor design software identification interface module 402 can select a second input image 502 corresponding to a second electric motor design. The second electric motor design may be a variation of the first electric motor design or one of the reference electric motor designs 126 identified using the first electric motor design. The second electric motor design can have a second geometry, such as having one or more components (e.g., a bearing, a rotor, a stator) having respective geometric parameter(s) (e.g., a length of a bearing, a width of the bearing, etc.). In another example, the electric motor design software identification interface module 402 can select a second set of geometric parameters.

In some embodiments, block 1310 may be omitted from the process represented by the flowchart 1300. For example, instances of blocks 1302, 1304, 1306, 1308, and/or 1312 may be executed substantially in parallel to generate a plurality of performance evaluations substantially in parallel. For example, (i) a first instance of blocks 1302, 1304, 1306, 1308, and/or 1312 can be executed to generate a first performance evaluation for the first electric motor design and (ii) a second instance of blocks 1302, 1304, 1306, 1308, and/or 1312 can be executed to generate a second performance evaluation for the second electric motor design substantially in parallel.

If, at block 1310, the electric motor design evaluation service 120 determines to select another electric motor design to evaluate, control returns to block 1302 to select another electric motor design to evaluate. Otherwise, control proceeds to block 1312.

At block 1312, the electric motor design evaluation service 120 may output the performance evaluation(s) of the electric motor design(s). For example, the electric motor design software identification interface module 402 can output the performance evaluation 512 for at least the first electric motor design and the second electric motor design to the electric motor design identification software 102. After outputting the performance evaluation(s) of the electric motor design(s) at block 1312, the example flowchart 1300 of FIG. 13 concludes.

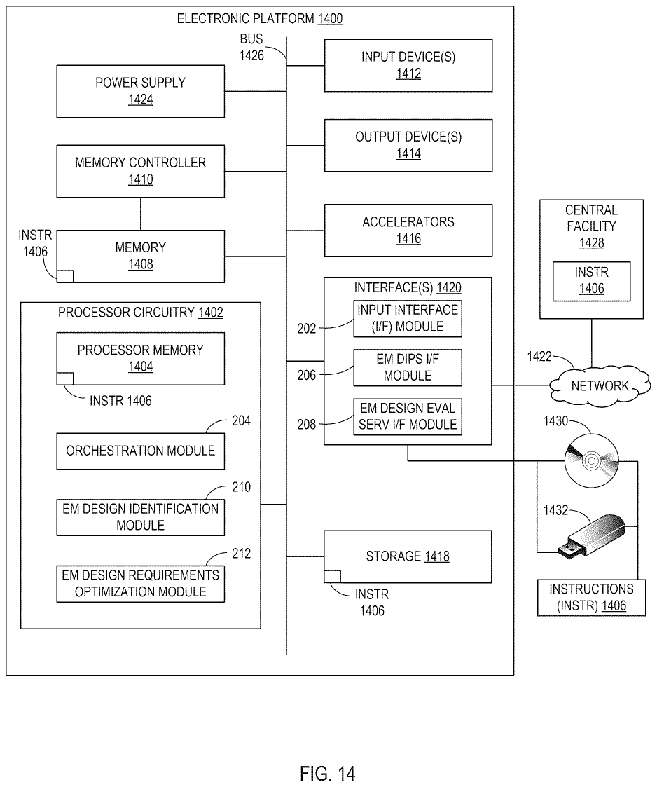

FIG. 14 is an example implementation of an electronic platform 1400 structured to execute the machine-readable instructions of FIGS. 12 and/or 13 to implement the electric motor design identification software 102 of FIGS. 1 and/or 2. It should be appreciated that FIG. 14 is intended neither to be a description of necessary components for an electronic and/or computing device to operate as the electric motor design identification software 102, in accordance with the techniques described herein, nor a comprehensive depiction.

The electronic platform 1400 of this example may be an electronic device, such as a desktop computer, a laptop computer, a tablet computer, a server (e.g., a computer server, a blade server, a rack-mounted server, etc.), a wearable device (e.g., an augmented reality and/or virtual reality (AR/VR) device, a heads-up display (HUD) device, smart glasses, smart goggles, etc.), a workstation, or any other type of computing and/or electronic device.

The electronic platform 1400 of the illustrated example includes processor circuitry 1402, which may be implemented by one or more programmable processors, one or more hardware-implemented state machines, one or more ASICs, etc., and/or any combination(s) thereof. For example, the one or more programmable processors may include one or more CPUs, one or more DSPs, one or more FPGAs, one or more GPUs, etc., and/or any combination(s) thereof. The processor circuitry 1402 includes processor memory 1404, which may be volatile memory, such as random-access memory (RAM) of any type. The processor circuitry 1402 of this example implements the orchestration module 204, the electric motor design identification module 210, and the electric motor design requirements optimization module 212 of FIG. 2.

The processor circuitry 1402 may execute machine-readable instructions 1406 (identified by INSTRUCTIONS), which are stored in the processor memory 1404, to implement at least one of the orchestration module 204, the electric motor design identification module 210, or the electric motor design requirements optimization module 212 of FIG. 2. The machine-readable instructions 1406 may include data representative of computer-executable and/or machine-executable instructions implementing techniques that operate according to the techniques described herein. For example, the machine-readable instructions 1406 may include data (e.g., code, embedded software (e.g., firmware), software, etc.) representative of the flowcharts of FIGS. 12 and/or 13, or portion(s) thereof.

The electronic platform 1400 includes memory 1408, which may include the instructions 1406. The memory 1408 of this example may be controlled by a memory controller 1410. For example, the memory controller 1410 may control reads, writes, and/or, more generally, access(es) to the memory 1408 by other component(s) of the electronic platform 1400. The memory 1408 of this example may be implemented by volatile memory, non-volatile memory, etc., and/or any combination(s) thereof. For example, the volatile memory may include static random-access memory (SRAM), dynamic random-access memory (DRAM), cache memory (e.g., Level 1 (L1 ) cache memory, Level 2 (L2) cache memory, Level 3 (L3) cache memory, etc.), etc., and/or any combination(s) thereof. In some examples, the non-volatile memory may include Flash memory, electrically erasable programmable read-only memory (EEPROM), magnetoresistive random-access memory (MRAM), ferroelectric random-access memory (FeRAM, F-RAM, or FRAM), etc., and/or any combination(s) thereof.

The electronic platform 1400 includes input device(s) 1412 to enable data and/or commands to be entered into the processor circuitry 1402. For example, the input device(s) 1412 may include an audio sensor, a camera (e.g., a still camera, a video camera, etc.), a keyboard, a microphone, a mouse, a touchscreen, a voice recognition system, etc., and/or any combination(s) thereof.

The electronic platform 1400 includes output device(s) 1414 to convey, display, and/or present information to a user (e.g., a human user, a machine user, etc.). For example, the output device(s) 1414 may include one or more display devices, speakers, etc. The one or more display devices may include an augmented reality (AR) and/or virtual reality (VR) display, a liquid crystal display (LCD), a light-emitting diode (LED) display, an organic light-emitting diode (OLED) display, a quantum dot (QLED) display, a thin-film transistor (TFT) LCD, a touchscreen, etc., and/or any combination(s) thereof. The output device(s) 1414 can be used, among other things, to generate, launch, and/or present a user interface. For example, the user interface may be generated and/or implemented by the output device(s) 1414 for visual presentation of output and speakers or other sound generating devices for audible presentation of output.

The electronic platform 1400 includes accelerators 1416, which are hardware devices to which the processor circuitry 1402 may offload compute tasks to accelerate their processing. For example, the accelerators 1416 may include artificial intelligence/machine-learning (AI/ML) processors, ASICs, FPGAs, graphics processing units (GPUs), neural network (NN) processors, systems-on-chip (SoCs), vision processing units (VPUs), etc., and/or any combination(s) thereof. In some examples, one or more of the orchestration module 204, the electric motor design identification module 210, and/or the electric motor design requirements optimization module 212 may be implemented by one(s) of the accelerators 1416 instead of the processor circuitry 1402. In some examples, the orchestration module 204, the electric motor design identification module 210, and/or the electric motor design requirements optimization module 212 may be executed concurrently (e.g., in parallel, substantially in parallel, etc.) by the processor circuitry 1402 and the accelerators 1416. For example, the processor circuitry 1402 and one(s) of the accelerators 1416 may execute in parallel function(s) corresponding to the electric motor design requirements optimization module 212.

The electronic platform 1400 includes storage 1418 to record and/or control access to data, such as the machine-readable instructions 1406. In some embodiments, the storage 1418 may implement the reference electric motor design datastore 128 of FIG. 1. The storage 1418 may be implemented by one or more mass storage disks or devices, such as HDDs, SSDs, etc., and/or any combination(s) thereof.

The electronic platform 1400 includes interface(s) 1420 to effectuate exchange of data with external devices (e.g., computing and/or electronic devices of any kind) via a network 1422. In this example, the interface(s) 1420 implement(s) the input interface module 202, the electric motor image processing service interface module 206 (identified by “EM DIPS I/F MODULE”), and the electric motor evaluation service interface module 208 (identified by “EM DESIGN EVAL SERV I/F MODULE”) of FIG. 2.

The interface(s) 1420 of the illustrated example may be implemented by an interface device, such as network interface circuitry (e.g., a NIC, a smart NIC, etc.), a gateway, a router, a switch, etc., and/or any combination(s) thereof. The interface(s) 1420 may implement any type of communication interface, such as BLUETOOTH®, a cellular telephone system (e.g., a 4G LTE interface, a 5G interface, a future generation 6G interface, etc.), an Ethernet interface, a near-field communication (NFC) interface, an optical disc interface (e.g., a Blu-ray disc drive, a Compact Disk (CD) drive, a Digital Versatile Disk (DVD) drive, etc.), an optical fiber interface, a satellite interface (e.g., a BLOS satellite interface, a LOS satellite interface, etc.), a Universal Serial Bus (USB) interface (e.g., USB Type-A, USB Type-B, USB TYPE-C™ or USB-C™, etc.), etc., and/or any combination(s) thereof.

The electronic platform 1400 includes a power supply 1424 to store energy and provide power to components of the electronic platform 1400. The power supply 1424 may be implemented by a power converter, such as an alternating current-to-direct-current (AC/DC) power converter, a direct current-to-direct current (DC/DC) power converter, etc., and/or any combination(s) thereof. For example, the power supply 1424 may be powered by an external power source, such as an alternating current (AC) power source (e.g., an electrical grid), a direct current (DC) power source (e.g., a battery, a battery backup system, etc.), etc., and the power supply 1424 may convert the AC input or the DC input into a suitable voltage for use by the electronic platform 1400. In some examples, the power supply 1424 may be a limited duration power source, such as a battery (e.g., a rechargeable battery such as a lithium-ion battery).

Component(s) of the electronic platform 1400 may be in communication with one(s) of each other via a bus 1426. For example, the bus 1426 may be any type of computing and/or electrical bus, such as an Inter-Integrated Circuit (I2C) bus, a Peripheral Component Interconnect (PCI) bus, a Peripheral Component Interconnect Express (PCIe) bus, a Serial Peripheral Interface (SPI) bus, and/or the like.

The network 1422 may be implemented by any wired and/or wireless network(s) such as one or more cellular networks (e.g., 4G LTE cellular networks, 5G cellular networks, future generation 6G cellular networks, etc.), one or more data buses, one or more local area networks (LANs), one or more optical fiber networks, one or more private networks, one or more public networks, one or more wireless local area networks (WLANs), etc., and/or any combination(s) thereof. For example, the network 1422 may be the Internet, but any other type of private and/or public network is contemplated.

The network 1422 of the illustrated example facilitates communication between the interface(s) 1420 and a central facility 1428. The central facility 1428 in this example may be an entity associated with one or more servers, such as one or more physical hardware servers and/or virtualizations of the one or more physical hardware servers. For example, the central facility 1428 may be implemented by a public cloud provider, a private cloud provider, etc., and/or any combination(s) thereof. In this example, the central facility 1428 may compile, generate, update, etc., the machine-readable instructions 1406 and store the machine-readable instructions 1406 for access (e.g., download) via the network 1422. For example, the electronic platform 1400 may transmit a request, via the interface(s) 1420, to the central facility 1428 for the machine-readable instructions 1406 and receive the machine-readable instructions 1406 from the central facility 1428 via the network 1422 in response to the request.

Additionally or alternatively, the interface(s) 1420 may receive the machine-readable instructions 1406 via non-transitory machine-readable storage media, such as an optical disc 1430 (e.g., a Blu-ray disc, a CD, a DVD, etc.) or any other type of removable non-transitory machine-readable storage media such as a USB drive 1432. For example, the optical disc 1430 and/or the USB drive 1432 may store the machine-readable instructions 1406 thereon and provide the machine-readable instructions 1406 to the electronic platform 1400 via the interface(s) 1420.

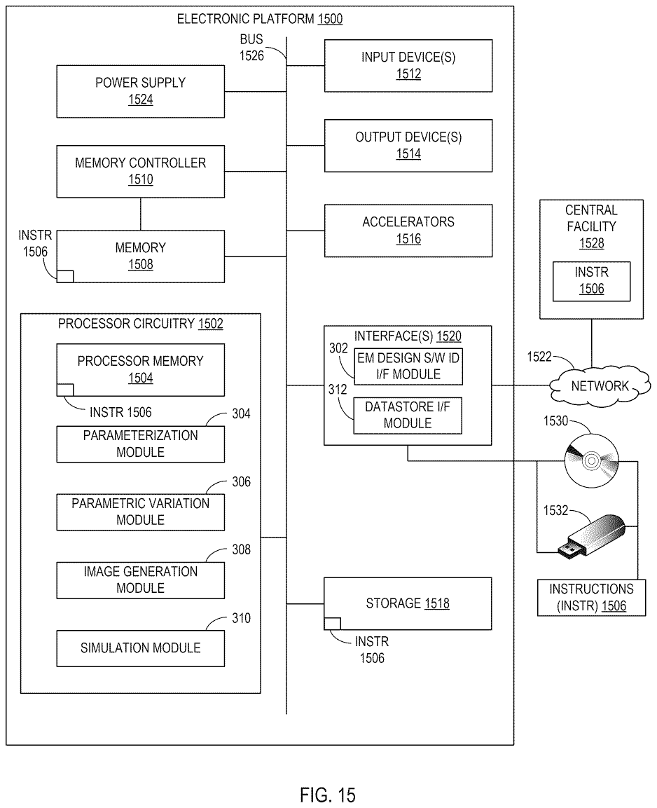

FIG. 15 is an example implementation of an electronic platform 1500 structured to execute the machine-readable instructions of FIGS. 12 and/or 13 to implement the electric motor design image processing service 114 of FIGS. 1 and/or 3. It should be appreciated that FIG. 15 is intended neither to be a description of necessary components for an electronic and/or computing device to operate as the electric motor design identification software 102, in accordance with the techniques described herein, nor a comprehensive depiction.

The electronic platform 1500 of this example may be an electronic device, such as a desktop computer, a laptop computer, a tablet computer, a server (e.g., a computer server, a blade server, a rack-mounted server, etc.), a wearable device (e.g., an AR/VR device, a HUD device, smart glasses, smart goggles, etc.), a workstation, or any other type of computing and/or electronic device.

The electronic platform 1500 of the illustrated example includes processor circuitry 1502, which may be implemented by one or more programmable processors, one or more hardware-implemented state machines, one or more ASICs, etc., and/or any combination(s) thereof. For example, the one or more programmable processors may include one or more CPUs, one or more DSPs, one or more FPGAs, one or more GPUs, etc., and/or any combination(s) thereof. The processor circuitry 1502 includes processor memory 1504, which may be volatile memory, such as RAM of any type. The processor circuitry 1502 of this example implements the parameterization module 304, the parameter variation module 306, the image generation module 308, and the simulation module 310 of FIG. 3.

The processor circuitry 1502 may execute machine-readable instructions 1506 (identified by INSTRUCTIONS), which are stored in the processor memory 1504, to implement at least one of the parameterization module 304, the parameter variation module 306, the image generation module 308, or the simulation module 310 of FIG. 3. The machine-readable instructions 1506 may include data representative of computer-executable and/or machine-executable instructions implementing techniques that operate according to the techniques described herein. For example, the machine-readable instructions 1506 may include data (e.g., code, embedded software (e.g., firmware), software, etc.) representative of the flowcharts of FIGS. 12 and/or 13, or portion(s) thereof.

The electronic platform 1500 includes memory 1508, which may include the instructions 1506. The memory 1508 of this example may be controlled by a memory controller 1510. For example, the memory controller 1510 may control reads, writes, and/or, more generally, access(es) to the memory 1508 by other component(s) of the electronic platform 1500. The memory 1508 of this example may be implemented by volatile memory, non-volatile memory, etc., and/or any combination(s) thereof. For example, the volatile memory may include SRAM, DRAM, cache memory (e.g., Level 1 (L1) cache memory, L2 cache memory, L3 cache memory, etc.), etc., and/or any combination(s) thereof. In some examples, the non-volatile memory may include Flash memory, EEPROM, MRAM, FRAM, etc., and/or any combination(s) thereof.

The electronic platform 1500 includes input device(s) 1512 to enable data and/or commands to be entered into the processor circuitry 1502. For example, the input device(s) 1512 may include an audio sensor, a camera (e.g., a still camera, a video camera, etc.), a keyboard, a microphone, a mouse, a touchscreen, a voice recognition system, etc., and/or any combination(s) thereof.

The electronic platform 1500 includes output device(s) 1514 to convey, display, and/or present information to a user (e.g., a human user, a machine user, etc.). For example, the output device(s) 1514 may include one or more display devices, speakers, etc. The one or more display devices may include an AR and/or VR display, an LCD, an LED display, an OLED display, a QLED display, a TFT LCD, a touchscreen, etc., and/or any combination(s) thereof. The output device(s) 1514 can be used, among other things, to generate, launch, and/or present a user interface. For example, the user interface may be generated and/or implemented by the output device(s) 1514 for visual presentation of output and speakers or other sound generating devices for audible presentation of output.

The electronic platform 1500 includes accelerators 1516, which are hardware devices to which the processor circuitry 1502 may offload compute tasks to accelerate their processing. For example, the accelerators 1516 may include AI/ML processors, ASICs, FPGAs, GPUs, NN processors, SoCs, VPUs, etc., and/or any combination(s) thereof. In some examples, one or more of the parameterization module 304, the parameter variation module 306, the image generation module 308, and/or the simulation module 310 may be implemented by one(s) of the accelerators 1516 instead of the processor circuitry 1502. In some examples, the parameterization module 304, the parameter variation module 306, the image generation module 308, and/or the simulation module 310 may be executed concurrently (e.g., in parallel, substantially in parallel, etc.) by the processor circuitry 1502 and the accelerators 1516. For example, the processor circuitry 1502 and one(s) of the accelerators 1516 may execute in parallel function(s) corresponding to the image generation module 308.

The electronic platform 1500 includes storage 1518 to record and/or control access to data, such as the machine-readable instructions 1506. In some embodiments, the storage 1518 may implement the reference electric motor design datastore 128 of FIG. 1. The storage 1518 may be implemented by one or more mass storage disks or devices, such as HDDs, SSDs, etc., and/or any combination(s) thereof.

The electronic platform 1500 includes interface(s) 1520 to effectuate exchange of data with external devices (e.g., computing and/or electronic devices of any kind) via a network 1522. In this example, the interface(s) 1520 implement(s) the electric motor design software identification interface module 302 (identified by “EM DESIGN S/W ID I/F MODULE”) and the datastore interface module 312 (identified by “DATASTORE I/F MODULE”) of FIG. 3.

The interface(s) 1520 of the illustrated example may be implemented by an interface device, such as network interface circuitry (e.g., a NIC, a smart NIC, etc.), a gateway, a router, a switch, etc., and/or any combination(s) thereof. The interface(s) 1520 may implement any type of communication interface, such as BLUETOOTH®, a cellular telephone system (e.g., a 4G LTE interface, a 5G interface, a future generation 6G interface, etc.), an Ethernet interface, an NFC interface, an optical disc interface (e.g., a Blu-ray disc drive, a CD drive, a DVD drive, etc.), an optical fiber interface, a satellite interface (e.g., a BLOS satellite interface, a LOS satellite interface, etc.), a USB interface (e.g., USB Type-A, USB Type-B, USB TYPE-C™ or USB-C™, etc.), etc., and/or any combination(s) thereof.

The electronic platform 1500 includes a power supply 1524 to store energy and provide power to components of the electronic platform 1500. The power supply 1524 may be implemented by a power converter, such as an AC/DC power converter, a DC/DC power converter, etc., and/or any combination(s) thereof. For example, the power supply 1524 may be powered by an external power source, such as an AC power source (e.g., an electrical grid), a DC power source (e.g., a battery, a battery backup system, etc.), etc., and the power supply 1524 may convert the AC input or the DC input into a suitable voltage for use by the electronic platform 1500. In some examples, the power supply 1524 may be a limited duration power source, such as a battery (e.g., a rechargeable battery such as a lithium-ion battery).

Component(s) of the electronic platform 1500 may be in communication with one(s) of each other via a bus 1526. For example, the bus 1526 may be any type of computing and/or electrical bus, such as an I2C bus, a PCI bus, a PCIe bus, a SPI bus, and/or the like.

The network 1522 may be implemented by any wired and/or wireless network(s) such as one or more cellular networks (e.g., 4G LTE cellular networks, 5G cellular networks, future generation 6G cellular networks, etc.), one or more data buses, one or more LANs, one or more optical fiber networks, one or more private networks, one or more public networks, one or more WLANs, etc., and/or any combination(s) thereof. For example, the network 1522 may be the Internet, but any other type of private and/or public network is contemplated.

The network 1522 of the illustrated example facilitates communication between the interface(s) 1520 and a central facility 1528. The central facility 1528 in this example may be an entity associated with one or more servers, such as one or more physical hardware servers and/or virtualizations of the one or more physical hardware servers. For example, the central facility 1528 may be implemented by a public cloud provider, a private cloud provider, etc., and/or any combination(s) thereof. In this example, the central facility 1528 may compile, generate, update, etc., the machine-readable instructions 1506 and store the machine-readable instructions 1506 for access (e.g., download) via the network 1522. For example, the electronic platform 1500 may transmit a request, via the interface(s) 1520, to the central facility 1528 for the machine-readable instructions 1506 and receive the machine-readable instructions 1506 from the central facility 1528 via the network 1522 in response to the request.

Additionally or alternatively, the interface(s) 1520 may receive the machine-readable instructions 1506 via non-transitory machine-readable storage media, such as an optical disc 1530 (e.g., a Blu-ray disc, a CD, a DVD, etc.) or any other type of removable non-transitory machine-readable storage media such as a USB drive 1532. For example, the optical disc 1530 and/or the USB drive 1532 may store the machine-readable instructions 1506 thereon and provide the machine-readable instructions 1506 to the electronic platform 1500 via the interface(s) 1520.

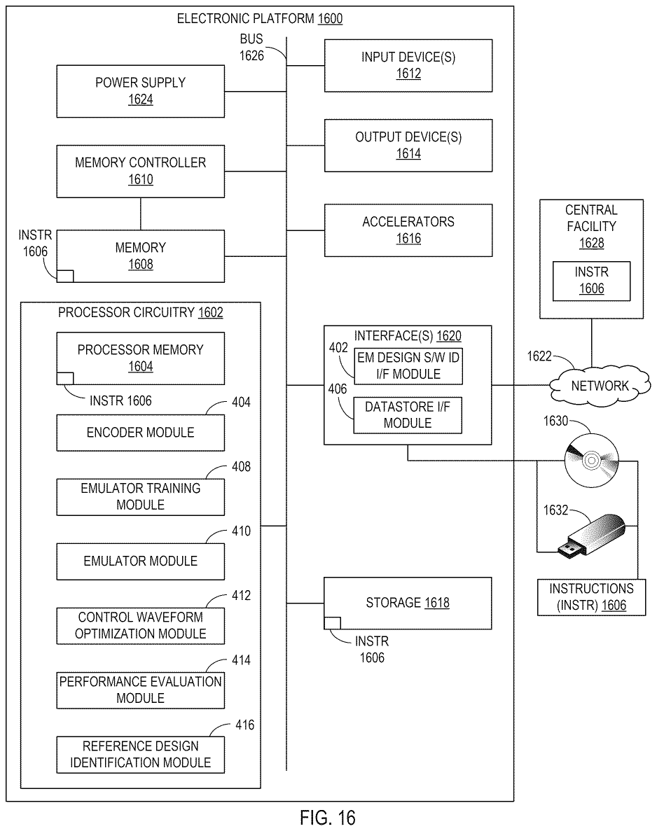

FIG. 16 is an example implementation of an electronic platform 1600 structured to execute the machine-readable instructions of FIGS. 12 and/or 13 to implement the electric motor design image processing service 114 of FIGS. 1 and/or 3. It should be appreciated that FIG. 16 is intended neither to be a description of necessary components for an electronic and/or computing device to operate as the electric motor design identification software 102, in accordance with the techniques described herein, nor a comprehensive depiction.

The electronic platform 1600 of this example may be an electronic device, such as a desktop computer, a laptop computer, a tablet computer, a server (e.g., a computer server, a blade server, a rack-mounted server, etc.), a wearable device (e.g., an AR/VR device, a HUD device, smart glasses, smart goggles, etc.), a workstation, or any other type of computing and/or electronic device.

The electronic platform 1600 of the illustrated example includes processor circuitry 1602, which may be implemented by one or more programmable processors, one or more hardware-implemented state machines, one or more ASICs, etc., and/or any combination(s) thereof. For example, the one or more programmable processors may include one or more CPUs, one or more DSPs, one or more FPGAs, one or more GPUs, etc., and/or any combination(s) thereof. The processor circuitry 1602 includes processor memory 1604, which may be volatile memory, such as RAM of any type. The processor circuitry 1602 of this example implements the encoder module 404, the emulator training module 408, the emulator module 410, the control waveform optimization module 412, the performance evaluation module 414, and the reference design identification module 416 of FIGS. 4-6.

The processor circuitry 1602 may execute machine-readable instructions 1606 (identified by INSTRUCTIONS), which are stored in the processor memory 1604, to implement at least one of the encoder module 404, the emulator training module 408, the emulator module 410, the control waveform optimization module 412, the performance evaluation module 414, or the reference design identification module 416 of FIG. 4. The machine-readable instructions 1606 may include data representative of computer-executable and/or machine-executable instructions implementing techniques that operate according to the techniques described herein. For example, the machine-readable instructions 1606 may include data (e.g., code, embedded software (e.g., firmware), software, etc.) representative of the flowcharts of FIGS. 12 and/or 13, or portion(s) thereof.

The electronic platform 1600 includes memory 1608, which may include the instructions 1606. The memory 1608 of this example may be controlled by a memory controller 1610. For example, the memory controller 1610 may control reads, writes, and/or, more generally, access(es) to the memory 1608 by other component(s) of the electronic platform 1600. The memory 1608 of this example may be implemented by volatile memory, non-volatile memory, etc., and/or any combination(s) thereof. For example, the volatile memory may include SRAM, DRAM, cache memory (e.g., Level 1 (L1) cache memory, L2 cache memory, L3 cache memory, etc.), etc., and/or any combination(s) thereof. In some examples, the non-volatile memory may include Flash memory, EEPROM, MRAM, FRAM, etc., and/or any combination(s) thereof.

The electronic platform 1600 includes input device(s) 1612 to enable data and/or commands to be entered into the processor circuitry 1602. For example, the input device(s) 1612 may include an audio sensor, a camera (e.g., a still camera, a video camera, etc.), a keyboard, a microphone, a mouse, a touchscreen, a voice recognition system, etc., and/or any combination(s) thereof.

The electronic platform 1600 includes output device(s) 1614 to convey, display, and/or present information to a user (e.g., a human user, a machine user, etc.). For example, the output device(s) 1614 may include one or more display devices, speakers, etc. The one or more display devices may include an AR and/or VR display, an LCD, an LED display, an OLED display, a QLED display, a TFT LCD, a touchscreen, etc., and/or any combination(s) thereof. The output device(s) 1614 can be used, among other things, to generate, launch, and/or present a user interface. For example, the user interface may be generated and/or implemented by the output device(s) 1614 for visual presentation of output and speakers or other sound generating devices for audible presentation of output.

The electronic platform 1600 includes accelerators 1616, which are hardware devices to which the processor circuitry 1602 may offload compute tasks to accelerate their processing. For example, the accelerators 1616 may include AI/ML processors, ASICs, FPGAs, GPUs, NN processors, SoCs, VPUs, etc., and/or any combination(s) thereof. In some examples, one or more of the encoder module 404, the emulator training module 408, the emulator module 410, the control waveform optimization module 412, the performance evaluation module 414, and/or the reference design identification module 416 may be implemented by one(s) of the accelerators 1616 instead of the processor circuitry 1602. In some examples, the encoder module 404, the emulator training module 408, the emulator module 410, the control waveform optimization module 412, the performance evaluation module 414, and/or the reference design identification module 416 may be executed concurrently (e.g., in parallel, substantially in parallel, etc.) by the processor circuitry 1602 and the accelerators 1616. For example, the processor circuitry 1602 and one(s) of the accelerators 1616 may execute in parallel function(s) corresponding to the encoder module 404. In another example, the processor circuitry 1602 and one(s) of the accelerators 1616 may execute in parallel function(s) corresponding to the emulator module 410.

The electronic platform 1600 includes storage 1618 to record and/or control access to data, such as the machine-readable instructions 1606. In some embodiments, the storage 1618 may implement the reference electric motor design datastore 128 of FIG. 1. The storage 1618 may be implemented by one or more mass storage disks or devices, such as HDDs, SSDs, etc., and/or any combination(s) thereof.

The electronic platform 1600 includes interface(s) 1620 to effectuate exchange of data with external devices (e.g., computing and/or electronic devices of any kind) via a network 1622. In this example, the interface(s) 1620 implement(s) the electric motor design software identification interface module 402 (identified by “EM DESIGN S/W ID I/F MODULE”) and the datastore interface module 406 (identified by “DATASTORE I/F MODULE”) of FIG. 3.

The interface(s) 1620 of the illustrated example may be implemented by an interface device, such as network interface circuitry (e.g., a NIC, a smart NIC, etc.), a gateway, a router, a switch, etc., and/or any combination(s) thereof. The interface(s) 1620 may implement any type of communication interface, such as BLUETOOTH®, a cellular telephone system (e.g., a 4G LTE interface, a 5G interface, a future generation 6G interface, etc.), an Ethernet interface, an NFC interface, an optical disc interface (e.g., a Blu-ray disc drive, a CD drive, a DVD drive, etc.), an optical fiber interface, a satellite interface (e.g., a BLOS satellite interface, a LOS satellite interface, etc.), a USB interface (e.g., USB Type-A, USB Type-B, USB TYPE-C™ or USB-C™, etc.), etc., and/or any combination(s) thereof.

The electronic platform 1600 includes a power supply 1624 to store energy and provide power to components of the electronic platform 1600. The power supply 1624 may be implemented by a power converter, such as an AC/DC power converter, a DC/DC power converter, etc., and/or any combination(s) thereof. For example, the power supply 1624 may be powered by an external power source, such as an AC power source (e.g., an electrical grid), a DC power source (e.g., a battery, a battery backup system, etc.), etc., and the power supply 1624 may convert the AC input or the DC input into a suitable voltage for use by the electronic platform 1600. In some examples, the power supply 1624 may be a limited duration power source, such as a battery (e.g., a rechargeable battery such as a lithium-ion battery).

Component(s) of the electronic platform 1600 may be in communication with one(s) of each other via a bus 1626. For example, the bus 1626 may be any type of computing and/or electrical bus, such as an I2C bus, a PCI bus, a PCIe bus, a SPI bus, and/or the like.

The network 1622 may be implemented by any wired and/or wireless network(s) such as one or more cellular networks (e.g., 4G LTE cellular networks, 5G cellular networks, future generation 6G cellular networks, etc.), one or more data buses, one or more LANs, one or more optical fiber networks, one or more private networks, one or more public networks, one or more WLANs, etc., and/or any combination(s) thereof. For example, the network 1622 may be the Internet, but any other type of private and/or public network is contemplated.

The network 1622 of the illustrated example facilitates communication between the interface(s) 1620 and a central facility 1628. The central facility 1628 in this example may be an entity associated with one or more servers, such as one or more physical hardware servers and/or virtualizations of the one or more physical hardware servers. For example, the central facility 1628 may be implemented by a public cloud provider, a private cloud provider, etc., and/or any combination(s) thereof. In this example, the central facility 1628 may compile, generate, update, etc., the machine-readable instructions 1606 and store the machine-readable instructions 1606 for access (e.g., download) via the network 1622. For example, the electronic platform 1600 may transmit a request, via the interface(s) 1620, to the central facility 1628 for the machine-readable instructions 1606 and receive the machine-readable instructions 1606 from the central facility 1628 via the network 1622 in response to the request.

Additionally or alternatively, the interface(s) 1620 may receive the machine-readable instructions 1606 via non-transitory machine-readable storage media, such as an optical disc 1630 (e.g., a Blu-ray disc, a CD, a DVD, etc.) or any other type of removable non-transitory machine-readable storage media such as a USB drive 1632. For example, the optical disc 1630 and/or the USB drive 1632 may store the machine-readable instructions 1606 thereon and provide the machine-readable instructions 1606 to the electronic platform 1600 via the interface(s) 1620.

Techniques operating according to the principles described herein may be implemented in any suitable manner. The processing and decision blocks of the flowcharts above represent steps and acts that may be included in algorithms that carry out these various processes. Algorithms derived from these processes may be implemented as software integrated with and directing the operation of one or more single- or multi-purpose processors, may be implemented as functionally equivalent circuits such as a DSP circuit or an ASIC, or may be implemented in any other suitable manner. It should be appreciated that the flowcharts included herein do not depict the syntax or operation of any particular circuit or of any particular programming language or type of programming language. Rather, the flowcharts illustrate the functional information one skilled in the art may use to fabricate circuits or to implement computer software algorithms to perform the processing of a particular apparatus carrying out the types of techniques described herein. For example, the flowcharts, or portion(s) thereof, may be implemented by hardware alone (e.g., one or more analog or digital circuits, one or more hardware-implemented state machines, etc., and/or any combination(s) thereof) that is configured or structured to carry out the various processes of the flowcharts. In some examples, the flowcharts, or portion(s) thereof, may be implemented by machine-executable instructions (e.g., machine-readable instructions, computer-readable instructions, computer-executable instructions, etc.) that, when executed by one or more single- or multi-purpose processors, carry out the various processes of the flowcharts. It should also be appreciated that, unless otherwise indicated herein, the particular sequence of steps and/or acts described in each flowchart is merely illustrative of the algorithms that may be implemented and can be varied in implementations and embodiments of the principles described herein.

Accordingly, in some embodiments, the techniques described herein may be embodied in machine-executable instructions implemented as software, including as application software, system software, firmware, middleware, embedded code, or any other suitable type of computer code. Such machine-executable instructions may be generated, written, etc., using any of a number of suitable programming languages and/or programming or scripting tools, and also may be compiled as executable machine language code or intermediate code that is executed on a framework, virtual machine, or container.

When techniques described herein are embodied as machine-executable instructions, these machine-executable instructions may be implemented in any suitable manner, including as a number of functional facilities, each providing one or more operations to complete execution of algorithms operating according to these techniques. A “functional facility,” however instantiated, is a structural component of a computer system that, when integrated with and executed by one or more computers, causes the one or more computers to perform a specific operational role. A functional facility may be a portion of or an entire software element. For example, a functional facility may be implemented as a function of a process, or as a discrete process, or as any other suitable unit of processing. If techniques described herein are implemented as multiple functional facilities, each functional facility may be implemented in its own way; all need not be implemented the same way. Additionally, these functional facilities may be executed in parallel and/or serially, as appropriate, and may pass information between one another using a shared memory on the computer(s) on which they are executing, using a message passing protocol, or in any other suitable way.

Generally, functional facilities include routines, programs, objects, components, data structures, etc., that perform particular tasks or implement particular abstract data types. Typically, the functionality of the functional facilities may be combined or distributed as desired in the systems in which they operate. In some implementations, one or more functional facilities carrying out techniques herein may together form a complete software package. These functional facilities may, in alternative embodiments, be adapted to interact with other, unrelated functional facilities and/or processes, to implement a software program application.

Some exemplary functional facilities have been described herein for carrying out one or more tasks. It should be appreciated, though, that the functional facilities and division of tasks described is merely illustrative of the type of functional facilities that may implement using the exemplary techniques described herein, and that embodiments are not limited to being implemented in any specific number, division, or type of functional facilities. In some implementations, all functionalities may be implemented in a single functional facility. It should also be appreciated that, in some implementations, some of the functional facilities described herein may be implemented together with or separately from others (e.g., as a single unit or separate units), or some of these functional facilities may not be implemented.

Machine-executable instructions (e.g., processor-executable instructions) implementing the techniques described herein (when implemented as one or more functional facilities or in any other manner) may, in some embodiments, be encoded on one or more computer-readable media, machine-readable media, etc., to provide functionality to the media. Computer-readable media, machine-readable media, etc., include magnetic media such as a hard disk drive, optical media such as a CD or a DVD, a persistent or non-persistent solid-state memory (e.g., Flash memory, Magnetic RAM, etc.), or any other suitable storage media. Such a computer-readable medium, a machine-readable medium, etc., may be implemented in any suitable manner. As used herein, the terms “computer-readable media” (also called “computer-readable storage media”), “computer-readable medium” (also called “computer-readable storage medium”), “machine-readable media” (also called “machine-readable storage media”), and “machine-readable medium” (also called “machine-readable storage medium”) refer to tangible storage media. Tangible storage media are non-transitory and have at least one physical, structural component. In a “computer-readable medium” and “machine-readable medium” as used herein, at least one physical, structural component has at least one physical property that may be altered in some way during a process of creating the medium with embedded information, a process of recording information thereon, or any other process of encoding the medium with information. For example, a magnetization state of a portion of a physical structure of a computer-readable medium, a machine-readable medium, etc., may be altered during a recording process.

Further, some techniques described above comprise acts of storing information (e.g., data and/or instructions) in certain ways for use by these techniques. In some implementations of these techniques—such as implementations where the techniques are implemented as machine-executable instructions—the information may be encoded on a computer-readable storage media. Where specific structures are described herein as advantageous formats in which to store this information, these structures may be used to impart a physical organization of the information when encoded on the storage medium. These advantageous structures may then provide functionality to the storage medium by affecting operations of one or more processors interacting with the information; for example, by increasing the efficiency of computer operations performed by the processor(s).

In some, but not all, implementations in which the techniques may be embodied as machine-executable instructions, these instructions may be executed on one or more suitable computing device(s) and/or electronic device(s) operating in any suitable computer and/or electronic system, or one or more computing devices (or one or more processors of one or more computing devices) and/or one or more electronic devices (or one or more processors of one or more electronic devices) may be programmed to execute the machine-executable instructions. A computing device, electronic device, or processor (e.g., processor circuitry) may be programmed to execute instructions when the instructions are stored in a manner accessible to the computing device, electronic device, or processor, such as in a data store (e.g., an on-chip cache or instruction register, a computer-readable storage medium and/or a machine-readable storage medium accessible via a bus, a computer-readable storage medium and/or a machine-readable storage medium accessible via one or more networks and accessible by the device/processor, etc.). Functional facilities comprising these machine-executable instructions may be integrated with and direct the operation of a single multi-purpose programmable digital computing device, a coordinated system of two or more multi-purpose computing device sharing processing power and jointly carrying out the techniques described herein, a single computing device or coordinated system of computing device (co-located or geographically distributed) dedicated to executing the techniques described herein, one or more FPGAs for carrying out the techniques described herein, or any other suitable system.

Embodiments have been described where the techniques are implemented in circuitry and/or machine-executable instructions. It should be appreciated that some embodiments may be in the form of a method, of which at least one example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

Various aspects of the embodiments described above may be used alone, in combination, or in a variety of arrangements not specifically discussed in the embodiments described in the foregoing and is therefore not limited in its application to the details and arrangement of components set forth in the foregoing description or illustrated in the drawings. For example, aspects described in one embodiment may be combined in any manner with aspects described in other embodiments.

The phrase “and/or,” as used herein in the specification and in the claims, should be understood to mean “either or both,” of the elements so conjoined, e.g., elements that are conjunctively present in some cases and disjunctively present in other cases. Multiple elements listed with “and/or” should be construed in the same fashion, e.g., “one or more” of the elements so conjoined. Other elements may optionally be present other than the elements specifically identified by the “and/or” clause, whether related or unrelated to those elements specifically identified. Thus, as a non-limiting example, a reference to “A and/or B,” when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

The indefinite articles “a” and “an,” as used herein in the specification and in the claims, unless clearly indicated to the contrary, should be understood to mean “at least one.”

As used herein in the specification and in the claims, the phrase, “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently, “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

Also, the phraseology and terminology used herein is for the purpose of description and should not be regarded as limiting. The use of “including,” “comprising,” “having,” “containing,” “involving,” and variations thereof herein, is meant to encompass the items listed thereafter and equivalents thereof as well as additional items.

All definitions, as defined and used herein, should be understood to control over dictionary definitions, definitions in documents incorporated by reference, and/or ordinary meanings of the defined terms.

The word “exemplary” is used herein to mean serving as an example, instance, or illustration. Any embodiment, implementation, process, feature, etc., described herein as exemplary should therefore be understood to be an illustrative example and should not be understood to be a preferred or advantageous example unless otherwise indicated.

Having thus described several aspects of at least one embodiment, it is to be appreciated that various alterations, modifications, and improvements will readily occur to those skilled in the art. Such alterations, modifications, and improvements are intended to be part of this disclosure and are intended to be within the spirit and scope of the principles described herein. Accordingly, the foregoing description and drawings are by way of example only.

1. A method for characterizing an electric motor design using machine learning, comprising:
inputting a set of geometric parameters for an electric motor design to a first machine learning model and outputting, from the first machine learning model, an encoding of the set of geometric parameters; and
inputting a control waveform and the encoding of the set of geometric parameters to a second machine learning model and outputting, from the second machine learning model, a performance of the electric motor design under a variety of operating conditions and using the control waveform.

2. The method of claim 1, wherein at least one of the first machine learning model or the second machine learning model is a neural network.

3. The method of claim 2, wherein the first machine learning model is a vision transformer and the second machine learning model is a multilayer perceptron.

4. The method of claim 1, further comprising:
receiving a digital representation of the electric motor design; and
converting the digital representation into the set of geometric parameters.

5. The method of claim 4, wherein the digital representation is a computer-aided design file, a mesh model, a point cloud, or a text representation.

6. The method of claim 1, wherein the set of geometric parameters comprises geometric parameters associated with at least one of a flange bracket, a motor case, or a stator of the electric motor design.

7. The method of claim 1, wherein the set of input geometric parameters comprises geometric parameters associated with at least one of a bearing, a rotor, or a shaft of the electric motor design.

8. The method of claim 1, wherein the variety of operating conditions comprises rotor angle values and phase current values, and the second machine learning model is configured to output, using the rotor angle values and phase current values as input, at least one of torque values or flux linkage values as output.

9. The method of claim 1, wherein the variety of operating conditions comprises torque values and flux linkage values, and the second machine learning model is configured to output, using the torque values and flux linkage values as input, at least one of rotor angle values or phase current values as output.

10. The method of claim 1, wherein the variety of operating conditions comprises temperature values and battery state values, and the second machine learning model is configured to output, using the temperature values and battery state values as input, at least one loss value as output.

11. The method of claim 10, wherein the at least one loss comprises at least one of an ac loss, a core loss, an iron loss, a mechanical loss, an ohmic loss, or a stray loss.

12. At least one computer readable storage medium comprising processor executable instructions that, when executed, cause at least one hardware processor to at least:
input a set of geometric parameters for an electric motor design to a first machine learning model and output, from the first machine learning model, an encoding of the set of geometric parameters; and
input a control waveform and the encoding of the set of geometric parameters to a second machine learning model and output, from the second machine learning model, a performance of the electric motor design under a variety of operating conditions and using the control waveform.

13. The at least one computer readable storage medium of claim 12, wherein the at least one of the first machine learning model or the second machine learning model is a neural network.

14. The at least one computer readable storage medium of claim 12, wherein the variety of operating conditions comprises rotor angle values and phase current values, and the second machine learning model is configured to output, using the rotor angle values and phase current values as input, at least one of torque values or flux linkage values as output.

15. The at least one computer readable storage medium of claim 12, wherein the variety of operating conditions comprises torque values and flux linkage values, and the second machine learning model is configured to output, using the torque values and flux linkage values as input, at least one of rotor angle values or phase current values as output.

16. The at least one computer readable storage medium of claim 12, wherein the variety of operating conditions comprises temperature values and battery state values, and the second machine learning model is configured to output, using the temperature values and battery state values as input, at least one loss value as output.

17. A system for characterizing an electric motor design using machine learning, comprising:
at least one hardware processor; and
at least one computer readable storage medium storing processor executable instructions that, when executed by the at least one hardware processor, cause the at least one hardware processor to:
input a set of geometric parameters for an electric motor design to a first machine learning model and output, from the first machine learning model, an encoding of the set of geometric parameters; and
input a control waveform and the encoding of the set of geometric parameters to a second machine learning model and output, from the second machine learning model, a performance of the electric motor design under a variety of operating conditions and using the control waveform.

18. The system of claim 17, wherein the variety of operating conditions comprises rotor angle values and phase current values, and the second machine learning model is configured to output, using the rotor angle values and phase current values as input, at least one of torque values or flux linkage values as output.

19. The system of claim 17, wherein the variety of operating conditions comprises torque values and flux linkage values, and the second machine learning model is configured to output, using the torque values and flux linkage values as input, at least one of rotor angle values or phase current values as output.

20. The system of claim 17, wherein the variety of operating conditions comprises temperature values and battery state values, and the second machine learning model is configured to output, using the temperature values and battery state values as input, at least one loss value as output.
